(19) United States
(12) Patent Application Publication
(10) Pub. No.: US 2025/0221258 A1
(43) Pub. Date: Jul. 3, 2025

(54) DISPLAY DEVICE

(71) Applicant: LG Display Co., Ltd., Seoul (KR)

(72) Inventors: Kwangsoo KIM, Incheon (KR); Wooyeong JANG, Seoul (KR)

(73) Assignee: LG Display Co., Ltd., Seoul (KR)

(21) Appl. No.: 18/798,297

(22) Filed: Aug. 8, 2024

(30) Foreign Application Priority Data
Dec. 27, 2023 (KR) 10-2023-0193616

(51) Int. Cl. H10K 59/80; H10K 59/40

(52) U.S. Cl. CPC H10K 59/873; H10K 59/40

(57) ABSTRACT

Disclosed is a display device in which a bezel area is reduced, rigidity of a display panel is improved to reduce crack defects in a bent portion thereof, thereby preventing quality defect, ensuring reliability, and implementing a narrow bezel. To this end, the display device includes a display panel including: a first area constituting a front surface thereof and including a display area and a bezel area; a bent area disposed under the first area; and a second area constituting a rear surface thereof and disposed under the bent area; and a sealing layer disposed on top of the display panel in the first area, disposed on an outer surface of a bent portion of the display panel in the bent area, and disposed under the display panel in the second area.

### CROSS-REFERENCE TO RELATED APPLICATION

This application claims priority from Korean Patent Application No. 10-2023-0193616 filed on Dec. 27, 2023 in the Korean Intellectual Property Office, and all the benefits accruing therefrom under 35 U.S.C. 119, the contents of which in its entirety are herein incorporated by reference.

### BACKGROUND

### Technical Field

The present disclosure relates to a display device, and more specifically, for example, without limitation, to a display device in which a crack defect in a display panel is reduced.

### Description of Related Art

A display device includes a display area that displays a screen and a non-display area formed along an outside of the display area. The display device requires not only a display panel to display the screen but also various additional components such as a driving integrated circuit or a circuit board.

The additional components may be located in the non-display area, or various connection components such as a flexible printed circuit board for connection of the additional components may be located in or connected to the non-display area.

In the display device, as an example, the non-display area includes a bezel area, which is bent, for example, at 180 degrees and/or is maintained in a permanently folded shape, without being limited thereto.

The description provided in the background section should not be assumed to be prior art merely because it is mentioned in or associated with the background section. The background section may include information that describes one or more aspects of the subject technology.

### SUMMARY

In an existing display device, the bezel area is bent at 180 degrees and is maintained in a permanently folded shape, resulting in cracks occurring in a bent portion and resulting in screen abnormalities.

Therefore, reliability is not secured due to a quality defect in the display device, and thus a stable narrow bezel is not implemented.

In order to solve the above-mentioned problem, the inventors of the present disclosure have invented a display device in which the crack defects in the bent portion are reduced by reducing the bezel area of the display device and improving the rigidity of the display panel, thereby preventing the quality defect, ensuring the reliability, and implementing a stable narrow bezel.

A purpose of an exemplary embodiment of the present disclosure is to provide a display device in which a thickness of a reinforcement member to reinforce the bent portion of the display panel is adjusted, and a sealing layer on the display panel in the display area extends into a bent area in the non-display area, such that the thickness of the reinforcement member is adjusted based on a shape of the extending portion of the sealing layer.

Purposes according to the present disclosure are not limited to the above-mentioned purpose. Other purposes and advantages according to the present disclosure that are not mentioned may be understood based on following descriptions, and may be more clearly understood based on embodiments according to the present disclosure. Further, it will be easily understood that the purposes and advantages according to the present disclosure may be realized using means shown in the claims or combinations thereof.

A first aspect of the present disclosure provides a display device comprising: a display panel including: a first area constituting a front surface thereof and including a display area and a bezel area; a bent area disposed under the first area; and a second area constituting a rear surface thereof and disposed under the bent area; and a sealing layer disposed on top of the display panel in the first area, disposed on an outer surface of a bent portion of the display panel in the bent area, and disposed under the display panel in the second area.

A second aspect of the present disclosure provides a display device comprising: a display panel including: a first area constituting a front surface thereof and including a display area and a bezel area; a bent area disposed under the first area; and a second area constituting a rear surface thereof and disposed under the bent area; a gate driver configured to supply a gate signal to the display panel; a data driver configured to supply a data voltage to the display panel; a controller configured to control the gate driver and the data driver; a sealing layer disposed on top of the display panel in the first area, disposed on an outer surface of a bent portion of the display panel in the bent area, and disposed under the display panel in the second area; and a cover member disposed on top of the sealing layer in the first area.

According to the present disclosure, the scaling layer on the display panel of the display area may extend into the bent area of the non-display area, such that moisture infiltration into the bent area may be prevented by the sealing layer.

Furthermore, according to an exemplary embodiment of the present disclosure, the thickness of the reinforcement member (MCL) may be adjusted based on the shape of the portion of the sealing layer disposed extending from the display area into the bent area. Therefore, the bezel area at a lower end of the display panel may be reduced and the rigidity of the display panel may be improved.

Furthermore, according to an exemplary embodiment of the present disclosure, the sealing layer may extend from the display area into the bent area and the thickness thereof may be adjusted, such that the system space may be secured, and the risk of cracking in the bent portion may be minimized.

Furthermore, according to an exemplary embodiment of the present disclosure, during the manufacturing process of the display device, the sealing layer may be applied to the outer surface of the display panel in the bent area and then the back frame may be formed such that the amount of the ultraviolet ray irradiation into the display panel may be reduced due to the scaling layer.

Furthermore, according to an exemplary embodiment of the present disclosure, the cracks in and damage to the display panel may be reduced as the amount of the ultraviolet ray irradiation to the bent area of the display panel is reduced.

Furthermore, according to an exemplary embodiment of the present disclosure, the cracks in and the damage to the display panel may be prevented such that the rigidity of the display module may be improved, and the compressive rigidity of the bent portion of the display panel may be improved, thereby preventing a decrease in the lifespan of the display panel.

Furthermore, according to an exemplary embodiment of the present disclosure, as the back frame of the display device is made of the epoxy resin, the air gap within the display module may be eliminated and the rigidity of the module may be secured, thereby realizing a stable narrow bezel.

Furthermore, according to an example in the present disclosure, when an impact is applied to the bent portion of the display panel, the cushioning action of the epoxy resin has the effect of preventing the cracks in and damage to the display panel. This has the effect of providing a long-life, low-power display device.

In the display device according to the present disclosure, the sealing layer and the reinforcement member may protect the bent portion of the display panel during the display panel manufacturing process, thereby preventing the cracks in and damage to the display panel, and thus increasing the lifespan of the display panel and improving the quality of the display device.

The display device according to the present disclosure may prevent the cracks in the display panel and secure the rigidity of the display module to secure reliability thereof, thereby facilitating the implementation of the stable narrow bezel.

In addition to the above-described effects, the specific effects of the present disclosure are described below while describing specific details for implementing the embodiments of the disclosure.

Effects of the present disclosure are not limited to the effects mentioned above, and other effects not mentioned will be clearly understood by those skilled in the art from the descriptions below.

It is to be understood that both the foregoing general description and the following detailed description are exemplary and explanatory and are intended to provide further explanation of the inventive concepts as claimed.

### BRIEF DESCRIPTION OF DRAWINGS

The accompanying drawings, which are included to provide a further understanding of the disclosure and are incorporated in and constitute a part of this application, illustrate embodiments of the disclosure and together with the description serve to explain the principle of the disclosure. In the drawings:

FIG. 1A shows a front surface of a display device according to an exemplary embodiment of the present disclosure.

FIG. 1B shows a rear surface of a display device according to an exemplary embodiment of the present disclosure.

FIG. 2 is a cross-sectional view showing a cross-section taken along a cutting line (2-2)-th in FIG. 1 in a display device according to an exemplary embodiment of the present disclosure.

FIG. 3 is a diagram showing an example in which a sealing layer on a display panel has a constant thickness according to an exemplary embodiment of the present disclosure.

FIG. 4 is a diagram showing an example in which a sealing layer is thicker in a second area than in a first area according to another exemplary embodiment of the present disclosure.

FIG. 5 is a diagram showing an example in which a sealing layer is thicker in a first area than in a second area according to still another exemplary embodiment of the present disclosure.

FIG. 6 is a cross-sectional view of a display area including a touch structure under a sealing layer according to an exemplary embodiment of the present disclosure.

FIGS. 7 to 9 are diagrams showing examples in which a touch structure is applied to a sealing layer on a display panel according to an exemplary embodiment of the present disclosure.

FIGS. 10 to 12 are diagrams showing examples in which a system space changes based on a change in a thickness of a sealing layer according to an exemplary embodiment of the present disclosure.

FIGS. 13 to 15 are diagrams showing examples in which a thickness of a sealing layer changes based on a change in a thickness of a reinforcement member according to an exemplary embodiment of the present disclosure.

FIG. 16 is a block diagram schematically showing a system configuration of a display device according to an exemplary embodiment of the present disclosure.

Throughout the drawings and the detailed description, unless otherwise described, the same drawing reference numerals should be understood to refer to the same elements, features, and structures. The relative size and depiction of these elements may be exaggerated for clarity, illustration, and convenience.

### DETAILED DESCRIPTIONS

Reference will now be made in detail to embodiments of the present disclosure, examples of which may be illustrated in the accompanying drawings. The progression of processing steps and/or operations described is an example; however, the sequence of steps and/or operations is not limited to that set forth herein and may be changed as is known in the art, with the exception of steps and/or operations necessarily occurring in a particular order. Names of the respective elements used in the following explanations may be selected only for convenience of writing the specification and may be thus different from those used in actual products.

Advantages and features of the present disclosure, and a method of achieving the advantages and features will become apparent with reference to embodiments described later in detail together with the accompanying drawings. However, the present disclosure is not limited to the embodiments as disclosed under, but may be implemented in various different forms. Thus, these embodiments are set forth only to make the present disclosure complete, and to completely inform the scope of the present disclosure to those of ordinary skill in the technical field to which the present disclosure belongs, and the present disclosure is only defined by the scope of the claims.

For simplicity and clarity of illustration, elements in the drawings are not necessarily drawn to scale. The same reference numbers in different drawings represent the same or similar elements, and as such perform similar functionality. Further, descriptions and details of well-known steps and elements are omitted for simplicity of the description. Furthermore, in the following detailed description of the present disclosure, numerous specific details are set forth in order to provide a thorough understanding of the present disclosure. However, it will be understood that the present disclosure may be practiced without these specific details. In other instances, well-known methods, procedures, components, and circuits have not been described in detail so as not to unnecessarily obscure aspects of the present disclosure. Examples of various embodiments are illustrated and described further below. It will be understood that the description herein is not intended to limit the claims to the specific embodiments described. On the contrary, it is intended to cover alternatives, modifications, and equivalents as may be included within the spirit and scope of the present disclosure as defined by the appended claims.

A shape, a size, dimensions (e.g., length, width, height, thickness, radius, diameter, area, etc.), a ratio, an angle, a number, etc. disclosed in the drawings for illustrating embodiments of the present disclosure are illustrative, and the present disclosure is not limited thereto. A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

Any implementation described herein as an “example” is not necessarily to be construed as preferred or advantageous over other implementations.

The terminology used herein is directed to the purpose of describing particular embodiments only and is not intended to be limiting of the present disclosure. As used herein, the singular constitutes “a” and “an” are intended to include the plural constitutes as well, unless the context clearly indicates otherwise. It will be further understood that the terms “comprise”, “comprising”, “include”, and “including” when used in this specification, specify the presence of the stated features, integers, operations, elements, and/or components, but do not preclude the presence or addition of one or more other features, integers, operations, elements, components, and/or portions thereof. As used herein, the term “and/or” includes any and all combinations of one or more of associated listed items. Expression such as “at least one of” when preceding a list of elements may modify the entire list of elements and may not modify the individual elements of the list. In interpretation of numerical values, an error or tolerance therein may occur even when there is no explicit description thereof.

In addition, it will also be understood that when a first element or layer is referred to as being present “on” a second element or layer, the first element may be disposed directly on the second element or may be disposed indirectly on the second element with a third element or layer being disposed between the first and second elements or layers.

It will be understood that when an element or layer is referred to as being “connected to”, or “connected to” another element or layer, it may be directly on, connected to, or connected to the other element or layer, or one or more intervening elements or layers may be present. In addition, it will also be understood that when an element or layer is referred to as being “between” two elements or layers, it may be the only element or layer between the two elements or layers, or one or more intervening elements or layers may also be present.

Further, as used herein, when a layer, film, region, plate, or the like is disposed “on” or “on a top” of another layer, film, region, plate, or the like, the former may directly contact the latter or still another layer, film, region, plate, or the like is disposed between the former and the latter. As used herein, when a layer, film, region, plate, or the like is directly disposed “on” or “on a top” of another layer, film, region, plate, or the like, the former directly contacts the latter and still another layer, film, region, plate, or the like is not disposed between the former and the latter. Further, as used herein, when a layer, film, region, plate, or the like may be disposed “below” or “under” another layer, film, region, plate, or the like, the former may directly contact the latter or still another layer, film, region, plate, or the like may be disposed between the former and the latter. As used herein, when a layer, film, region, plate, or the like is directly disposed “below” or “under” another layer, film, region, plate, or the like, the former directly contacts the latter and still another layer, film, region, plate, or the like is not disposed between the former and the latter.

In descriptions of temporal relationships, for example, temporal precedent relationships between two events such as “after”, “subsequent to”, “before”, etc., another event may occur therebetween unless “directly after”, “directly subsequent” or “directly before” is not indicated.

The word “exemplary” is used to mean serving as an example or illustration. Aspects are example aspects. “Embodiments,” “examples,” “aspects,” and the like should not be construed as preferred or advantageous over other implementations. An embodiment, an example, an example embodiment, an aspect, or the like may refer to one or more embodiments, one or more examples, one or more example embodiments, one or more aspects, or the like, unless stated otherwise. Further, the term “may” encompasses all the meanings of the term “can.”

In describing a positional relationship, where the positional relationship between two parts (e.g., layers, films, regions, components, sections, or the like) is described, for example, using “on,” “upon,” “on top of,” “over,” “under,” “above,” “below,” “beneath,” “near,” “close to,” “adjacent to,” “beside,” “next to,” “at or on a side of,” or the like, one or more parts may be located between two other parts unless a more limiting term, such as “immediate(ly),” “direct(ly),” or “close(ly),” is used. For example, when a structure is described as being positioned “on,” “on a top of,” “upon,” “on top of,” “over,” “under,” “above,” “below,” “beneath,” “near,” “close to,” “adjacent to,” “beside,” “next to,” “at or on a side of,” or the like another structure, this description should be construed as including a case in which the structures contact each other as well as a case in which one or more additional structures are disposed or interposed therebetween. Furthermore, the terms “front,” “rear,” “back,” “left,” “right,” “top,” “bottom,” “downward,” “upward,” “upper,” “lower,” “up,” “down,” “column,” “row,” “vertical,” “horizontal,” and the like refer to an arbitrary frame of reference.

Spatially relative terms, such as “below,” “beneath,” “lower,” “on,” “above,” “upper” and the like, can be used to describe a correlation between various elements (e.g., layers, films, regions, components, sections, or the like) as shown in the drawings. The spatially relative terms are to be understood as terms including different orientations of the elements in use or in operation in addition to the orientation depicted in the drawings. For example, if the elements shown in the drawings are turned over, elements described as “below” or “beneath” other elements would be oriented “above” other elements. Thus, the term “below,” which is an example term, can include all directions of “above” and “below.” Likewise, an exemplary term “above” or “on” can include both directions of “above” and “below.”

When a certain embodiment may be implemented differently, a function or an operation specified in a specific block may occur in a different order from an order specified in a flowchart. For example, two blocks in succession may be actually performed substantially concurrently, or the two blocks may be performed in a reverse order depending on a function or operation involved.

It will be understood that, although the terms “first”, “second”, “third”, “A,” “B,” “(a),” and “(b),” and so on may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

The features of the various embodiments of the present disclosure may be partially or entirely combined with each other, and may be technically associated with each other or operate with each other. The embodiments may be implemented independently of each other and may be implemented together in an association relationship.

In interpreting a numerical value, the value is interpreted as including an error range unless there is no separate explicit description thereof.

Unless otherwise defined, all terms including technical and scientific terms used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

As used herein, “embodiments,” “examples,” “aspects, and the like should not be construed such that any aspect or design as described is superior to or advantageous over other aspects or designs.

Further, the term ‘or’ means ‘inclusive or’ rather than ‘exclusive or’. That is, unless otherwise stated or clear from the context, the expression that ‘x uses a or b’ means any one of natural inclusive permutations.

The terms used in the description below have been selected as being general and universal in the related technical field. However, there may be other terms than the terms depending on the development and/or change of technology, convention, preference of technicians, etc. Therefore, the terms used in the description below should not be understood as limiting technical ideas, but should be understood as examples of the terms for illustrating embodiments.

Further, in a specific case, a term may be arbitrarily selected by the applicant, and in this case, the detailed meaning thereof will be described in a corresponding description section. Therefore, the terms used in the description below should be understood based on not simply the name of the terms, but the meaning of the terms and the contents throughout the Detailed Descriptions.

Hereinafter, a display device according to an exemplary embodiment of the present disclosure is described in which during a panel manufacturing, a sealing layer of the display panel extends from the display area into a bent area to prevent moisture infiltration into the bent area, reduce a bezel area, and reduce or minimize the crack risk in the bent portion of the display panel, thereby improving a quality of the display device.

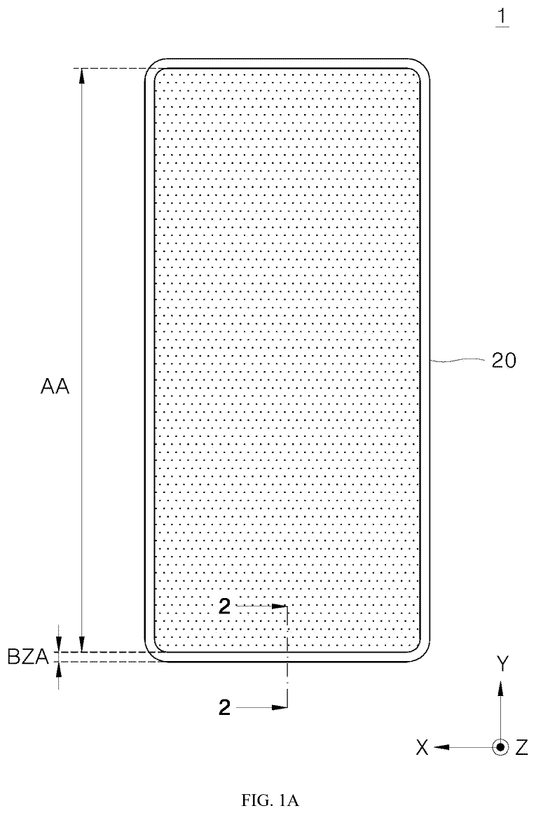

FIG. 1A shows a front surface of a display device according to an exemplary embodiment of the present disclosure. FIG. 1B shows a rear surface of the display device according to an exemplary embodiment of the present disclosure.

In other words, FIG. 1A briefly shows the front surface where a display area AA is located in a display device 1, and FIG. 1B briefly shows the rear surface of the display device 1. The front surface and an upward direction defined in the present disclosure refer to a Z-axis direction, and the rear surface and a downward direction defined in the present disclosure refer to a −Z-axis direction.

Referring to FIG. 1A and FIG. 1B, the display device 1 according to an exemplary embodiment of the present disclosure includes a cover member 20 disposed at the front surface and a back frame 30 disposed at the rear surface.

In this regard, as an example, the cover member 20 may include a cover window and/or a cover glass, without being limited thereto.

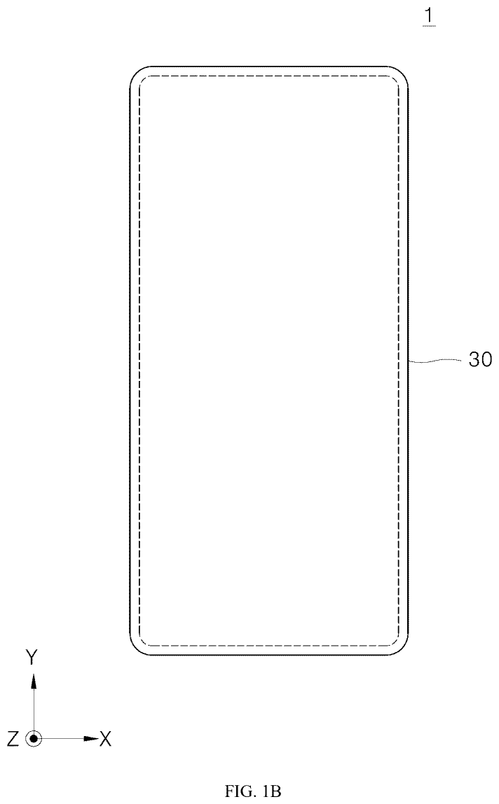

A display module may be disposed between a rear surface of the cover member 20 and an upper surface of the back frame 30. In this regard, the display module will be described in detail in FIG. 2, and may include, for example, a flexible substrate, a back plate, a reinforcement member, a protective member, and/or a connection member, without being Limited thereto.

The display device 1 may include a display area (Active Area) AA and a bezel area BZA at the front surface. The bezel area BZA may be disposed along the outermost edge of the display device 1 in a form that fully or partially surrounds the display area AA.

The cover member 20 may be disposed to cover a front surface of the display module and may serve to protect the display module from external shock.

An edge portion of the cover member 20 may have a rounded shape that is curved toward a rear surface thereof on which the display module is disposed, or may have a flat shape, without being limited thereto.

In this case, as an example, the cover member 20 may be disposed to cover up to at least a partial area of a side surface of the display module disposed on the rear surface thereof, and thus may serve to protect not only the front surface of the display module but also the side surface thereof from external impact.

Since the cover member 20 includes the display area AA that displays the screen, the cover member 20 may be made of a transparent material such as a cover glass to display the screen. For example, the cover member 20 may be made of transparent plastic, glass, or reinforced glass, without being limited thereto.

The back frame 30 may be disposed on the rear surface of the display module 17 and may accommodate therein the display module 17. As an example, the back frame 30 may contact the cover member 20 to support the cover member 20, or may be spaced apart from the cover member 20 with an intermediate member or a gap interposed therebetween, without being limited thereto.

The back frame 30 may serve as a housing that constitutes the rear surface and the outer edge of the display device 1. As an example, the back frame 30 may be made of a rigid material or a flexible material. As an example, the back frame 30 may be made of a metal material such as aluminum (Al) or an epoxy-based resin. Embodiments of the present disclosure are not limited thereto.

In this case, the back frame 30 may function as a casing constituting the outermost portion of the display device 1. Embodiments of the present disclosure are not limited thereto. For example, the back frame 30 may function as a middle frame that serves as a housing that protects the rear surface of the display module.

The display module according to an exemplary embodiment of the present disclosure will be described with reference to FIGS. 2 to 6.

FIG. 2 is a cross-sectional view showing a cross-section taken along a cutting line (2-2)-th in FIG. 1 in a display device according to an exemplary embodiment of the present disclosure. FIG. 2 is a cross-sectional view of a structure in which a sealing layer 200 extends from the display area AA into the bent area BA in the display device 1 according to an exemplary embodiment of the present disclosure.

Referring to FIG. 2, the display device 1 according to an exemplary embodiment of the present disclosure may include a display module 17, the cover member 20 disposed on top of the display module 17, and the back frame 30 that is disposed under the display module 17 and supports the display module 17 and/or the cover member 20.

The display module 17 may include a display panel 100. The display panel 100 may be referred to as a ‘flexible panel’. The display device 1 may include a first area 1A constituting a front surface thereof, and including the display area AA and the bezel area BZA, a bent area BA disposed under the first area 1A, and a second area 2A constituting a rear surface thereof, and disposed under the bent area BA.

The display device 1 may include the display module 17 having a portion disposed in the first area 1A, a portion disposed in the bent area BA, and a portion disposed in the second area 2A. That is, the display module 17 may be bent in the bent area BA so as to be disposed in the second area 2A.

The display module 17 may include the display panel 100 having a portion disposed in the first area 1A, a portion disposed in the bent area BA, and a portion disposed in the second area 2A. That is, the display panel 100 may be bent in the bent area BA so as to be disposed in the second area 2A.

In a plan view, the bent area BA may be located in the bezel area BZA of the display device 1. The bent area BA may be included between the first area 1A and the second area 2A in the vertical direction. The bent area BA may vertically overlap a portion of each of the first area 1A and the second area 2A while being disposed between the first area 1A and the second area 2A in the vertical direction.

The cover member 20 may be disposed on the display panel 100 and may include the bezel area BZA including the bent area BA and the display area AA in the plan view, and may include the first area 1A including the display area AA in a sectional view.

A front surface of the cover member 20 may be divided into the display area AA and the non-display area (non-Active area) NA as an area other than the display area AA. The non-display area NA may be formed along an edge of the display area AA and constitute the front surface of the cover member 20 and may be defined as the bezel area BZA.

The rear surface of the cover member 20 may include a first area 1A, a bent area BA, and a second area 2A in downward direction. The bent area BA may be disposed between the rear surface of the cover member 20 and the upper surface of the back frame 30. Embodiments are not limited thereto. As an example, the back frame 30 may not include a protruding portion (e.g., the bent area BA), or may include only a portion of the bent area BA. As an example, the cover member 20 may include a protruding portion, without being limited thereto.

The display module 17 coupled to the rear surface of the cover member 20 may include the bent area BA. The bent area BA may be disposed under the rear surface of the cover member 20 in the −Z-axis direction in the bezel area BZA.

In order to reduce the bezel area BZA of the rear surface of the cover member 20, it is advantageous to reduce the radius of curvature of the bent area BA. The radius of curvature of the bent area BA is proportional to a total thickness of each of the display module 17 and the display device 1. When the total thickness increases, the radius of curvature of the bent area BA increases, whereas when the total thickness decreases, the radius of curvature of the bent area BA decreases. Therefore, in order to avoid increasing the size of the bezel area BZA, it is advantageous to reduce or prevent increasing of the total thickness of each of the display module 17 and display device 1.

The sealing layer 200 may be disposed on the display panel 100 and in the first area 1A. The sealing layer 200 may be disposed on a side surface of the display panel 100 in the bent area BA, and may be disposed under the display panel 100 in the second area 2A.

The cover member 20 may be disposed on top of the sealing layer 200 in the first area 1A.

A reinforcement member 11 that reinforces the bending of the display panel 100 may be disposed on an outer surface of the sealing layer 200 in the bent area BA. In the second area 2A, the reinforcement member 11 may be disposed under the sealing layer 200.

The back frame 30 may be disposed under the cover member 20 in the bezel area BA. The back frame 30 may be disposed under the reinforcement member 11 and the bent portion of the display panel 100 in the second area 2A.

As an example, the reinforcement member 11 may be made of a rigid material or a flexible material. As an example, the reinforcement member 11 may be made of a metal material. As an example, the reinforcement member 11 may include a micro coating layer (MCL). The micro coating layer (MCL) may be referred to as a micro cover layer (MCL). Embodiments are not limited thereto. As an example, the reinforcement member 11 may be omitted depending on the design.

The reinforcement member 11 may extend so as to cover a portion of the display panel 100 in the bent area BA, and cover a portion of the display panel 100 in the first area 1A in contact with the bent area BA, and may cover a portion of the display panel 100 in the second area 2A.

The reinforcement member 11 may include resin, for example, ultraviolet (UV) curable acrylic resin. Embodiments of the present disclosure are not limited thereto.

As an example, the reinforcement member 11 may be made of a cured product of resin obtained by coating the resin and performing a curing process on the coated resin. When the resin is the ultraviolet curable resin, the resin may be cured using ultraviolet rays.

As an example, the reinforcement member 11 may be disposed on the outer surface of the display panel 100. As an example, the reinforcement member 11 may be disposed on the outer surface of the display panel 100 to cover various signal lines between an encapsulation portion and a pad of the display panel 100. Therefore, the reinforcement member 11 may reduce or prevent moisture penetration into the signal line while protecting the signal line from external shock.

Furthermore, the reinforcement member 11 may be disposed on the outer surface of the display panel 100 in the bent area BA and thus may supplement the rigidity of the display panel 100 in the bent area BA where a support member is absent. The support member may be adhered to a lower surface of the display panel 100 such that the support member is absent in an area corresponding to the bent area BA. As an example, when the display panel has been bent, a first support member BP1 may remain on the lower surface of the display panel 100 in the first area 1A, and a second support member BP2 may remain on a top surface of the bent portion of the display panel 100 in the second area 2A. Therefore, the rigidity of the display panel 100 in the bent area BA in which the support member is absent may be weakened. Thus, the rigidity thereof in the bent area BA may be supplemented by the reinforcement member 11 attached to the outer surface of the display panel 100 in the bent area BA.

The first area 1A vertically extends from the display panel 100 displaying the image to a top surface of the cover member 20 in an upward direction, and may be referred to as the display area AA in the vertical direction.

The second area 2A vertically extends from a top surface of the second support member BP2 to a bottom surface of the back frame 30 in a downward direction in which no image is displayed, and thus may be referred to as a non-display area NA in the vertical direction.

In a portion of the display module 17 in the first area 1A, the sealing layer 200 may be disposed on the display panel 100, and a polarization layer 14 may be formed on the scaling layer 200 through a first adhesive layer AD1, and the cover member 20 may be disposed on the polarization layer 14 through an optical adhesive layer 15. Embodiments are not limited thereto. As an example, the polarization layer 14, the first adhesive layer AD1 and/or the optical adhesive layer 15 may be omitted depending on the design. As an example, the reinforcement member 11 may be formed on the same layer as the polarization layer 14. As an example, the reinforcement member 11 may be in contact with a side surface of the polarization layer 14. As an example, the reinforcement member 11 may be spaced apart from the side surface of the polarization layer 14 such that a portion of the top surface of the sealing layer 200 may be exposed between the polarization layer 14 and the reinforcement member 11. As an example, the reinforcement member 11 may have a thickness smaller than that of the polarization layer 14 or may have a thickness equal to or greater than that of the polarization layer 14. As an example, the reinforcement member 11 may be extended from the side surface of the polarization layer 14 to the end of the c sealing layer 200. As an example, the reinforcement member 11 may be extended from the side surface of the polarization layer 14 to cover the end of the sealing layer 200. As an example, the reinforcement member 11 may be formed between the optical adhesive layer 15 and the sealing layer 200. As an example, the reinforcement member 11 may be in contact with a bottom surface of the optical adhesive layer 15 extending beyond the polarization layer 14.

In the first area 1A, as an example, the display module 17 may have a black matrix (not shown) disposed between the optical adhesive layer 15 and the cover member 20, without being limited thereto. The black matrix that light does not transmit through may be disposed in the non-display area NA or the bezel area BZA, and serves to reduce or prevent light leakage. Embodiments are not limited thereto. As an example, the black matrix may be omitted depending on the design.

As an example, in a portion of the display module 17 in the bent area BA, the first support member (Back Plate) BP1 may be disposed under the display panel 100 through a second adhesive layer AD2, and a plate 12 may be disposed under the support member BP1 through a third adhesive layer AD3. A connection member 13 may be disposed under the plate 12 through a fourth adhesive layer AD4. Embodiments are not limited thereto. As an example, the plate 12, the third adhesive layer AD3, the connection member 13 and/or the fourth adhesive layer AD4 may be omitted depending on the design.

As an example, in a portion of the display module 17 in the second area 2A, the second support member BP2 may be disposed under the connection member 13 through a fifth adhesive layer AD5. A bent portion of the display panel 100 may be disposed under the second support member BP2 through a sixth adhesive layer AD6. A bent portion of the sealing layer 200 may be disposed under the bent portion of the display panel 100. A bent portion of the reinforcement member 11 may be disposed under the bent portion of the sealing layer 200. Embodiments are not limited thereto. As an example, the adhesive layers may be omitted depending on the design. As an example, the second support member BP2, the sealing layer 200 and/or the reinforcement member 11 may to formed to have adhesiveness, without being limited thereto.

In the bent area BA, an area inwardly of the bent portion of the display panel 100 may be filled with a resin including an organic insulating material, without being limited thereto.

The sealing layer 200 may be disposed on the display panel 100 in the first area 1A. In the bent area BA, the sealing layer 200 may be disposed on the outer surface of the display panel 100. In the second area 2A, the sealing layer 200 may be disposed under the bent portion of the display panel 100.

The sealing layer 200 may be disposed on the outer surface of the display panel 100 in a portion of the second area A2 and the bent area BA. The sealing layer 200 may cover the display panel 100 in the bent area BA, and may extend to cover at least a portion or the entirety of the display panel 100 in the first area 1A that is in contact with the bent area BA, and cover at least a portion or the entirety of the display panel 100 in the second area A2.

The sealing layer 200 may have a flat shape in the first area 1A, a bent shape downwardly in the bent area BA, and a flat shape in the second area 2A.

As an example, the sealing layer 200 may include an epoxy resin, without being limited thereto.

The reinforcement member 11 may be disposed under the sealing layer 200 in the second area 2A. In the bent area BA, the reinforcement member 11 may be disposed on an outer surface of the sealing layer 200. As an example, the reinforcement member 11 may extend to cover at least a portion or the entirety of the sealing layer 200 in the second area 2A. As an example, the reinforcement member 11 may extend to be aligned with an end of the sealing layer 200 in the second area 2A, may expose at least a portion of the sealing layer 200 in the second area 2A or may cover the end of the sealing layer 200 in the second area 2A.

The back frame 30 may be disposed under the cover member 20 and the reinforcement member 11.

The back frame 30 may support the reinforcement member 11, support the bezel area BZA of the cover member 20, and support the first area 1A, the second area 2A, and the bent area BA of the display panel 100. For this purpose, the back frame 30 may be in contact with the cover member 20 in the first area 1A, and may be in contact with a side surface of the reinforcement member 11 in the bent area BA and may be in a contact with a bottom of the reinforcement member 11 in the second area 2A, and/or may contact the bent portion of the display panel 100 in the second area 2A. Embodiments are not limited thereto. As an example, the back frame 30 may not be in direct contact with the cover member 20 in the first area 1A, may not be in direct contact with the side surface of the reinforcement member 11 in the bent area BA, may not be in direct contact with the bottom of the reinforcement member 11 in the second area 2A, and/or may not directly contact the bent portion of the display panel 100 in the second area 2A.

As an example, the back frame 30 may include an epoxy resin. The epoxy resin may include an epoxy-based resin. Embodiments are not limited thereto. As an example, the back frame 30 may include any materials that could support the display panel 100.

The back frame 30 may have a flat portion and a vertical portion protruding perpendicularly and upwardly from an edge of the flat portion. The flat portion of the back frame 30 may be attached to a rear surface of the reinforcement member 110 by way of, for example, adhesive means of a resin or a tape. Embodiments of the present disclosure are not limited thereto. A top of a vertical portion of the back frame 30 may be adhered to the cover member 20 using, for example, a double-sided tape, without being limited thereto.

As an example, the back frame 30 has a box shape with an open top, and may accommodate the display module 17 therein, without being limited thereto. The display module 17 may include the display panel 100.

Since the back frame 30 according to an exemplary embodiment of the present disclosure is made of the epoxy resin, the back frame may be thinner and may effectively protect the bent area BA, thereby enabling a narrow bezel of the display device 1.

Since the back frame 30 according to an exemplary embodiment of the present disclosure is made of the epoxy resin, an air gap may be absent in the display module including the display panel 100 of the display device 1 such that micro movement of the display module may not occur. Thus, the back frame 30 may fix the display module in a more durable manner.

The display panel 100 may include the portion included in the first area 1A, the portion included in the bent area BA, and the portion included in the second area 2A in the vertical direction (Z direction). The first area 1A may correspond to the display area AA of the display panel 100, and the second area 2A may correspond to a pad PAD of the display panel 100. The first area 1A and the second area 2A may be disposed to face each other in the vertical direction (Z direction).

The display panel 100 may have a flat shape in the first area 1A, and may have a bent shape in the downward direction (−Z direction) in the bent area BA, and may have a flat shape extending inwardly from the bent area BA in the second area 2A.

As an example, in at least a portion or the entirety of the bent area BA, the first support member BP1 may be disposed under the display panel 100, without being limited thereto. The first support member BP1 may support the portion of the display panel 100 in the first area 1A. To this end, an upper surface of the first support member BP1 may be bonded to the lower surface of the display panel 100, for example, through the second adhesive layer AD2, without being limited thereto.

The first support member BP1 may be disposed under the lower surface of the display panel 100 to supplement the rigidity of the display panel 100 in the first area 1A, and allow a portion of the display panel 100 constituting the front surface to be maintained in a flat state.

The display device 1 may have the second support member BP2 disposed in the second area 2A. Th second support member BP2 may be disposed on top of the bent portion of the display panel 100.

Each of the first support member BP1 and the second support member BP2 may have a strength and a thickness above a certain value to supplement the rigidity of the display panel 100.

Since the first support member BP1 is formed to have a certain strength and thickness to supplement the rigidity of the display panel 100, the first support member BP1 is not formed on the bent portion of the display panel 100 having a curved shape in the bent area BA.

The second support member BP2 may support the display panel 100 in the second area 2A. For this purpose, a lower surface of the second support member BP2 may be bonded to an upper surface of the bent portion of the display panel 100, for example, through the sixth adhesive layer AD6, without being limited thereto.

The second support member BP2 may be vertically spaced apart from the first support member BP1 by a certain distance or greater and may be disposed on top of the display panel 100 in the second area 2A.

Based on a shape of the display panel 100 before being bent, the second support member BP2 may be disposed on the lower surface of the display panel 100 so as to be spaced apart from the first support member BP1 horizontally. The second support member BP2 may be disposed on the lower surface of the display panel 100 and may supplement the rigidity of the display panel 100 and maintain the display panel 100 in a flat state. Since the second support member BP2 is formed to have a certain strength and thickness to supplement the rigidity of the display panel 100, the second support member BP2 may not be formed on a portion of the display panel 100 corresponding to a portion of the bent area BA. Embodiments of the present disclosure are not limited thereto. As an example, the second support member BP2 may be formed to have a certain strength and thickness the same as or different from those of the first support member BP1. As an example, the second support member BP2 may include a material the same as or different from that of the first support member BP1. As an example, the second support member BP2 and the first support member BP1 may be integrally formed and then patterned, or may be formed separately.

After the display panel 100 has been bent, the second support member BP2 may be disposed on top of the display panel 100 in in the bent area BA and the second area 2A.

As an example, the plate 12 having a flat shape may be disposed between the first support member BP1 and the second support member BP2.

The plate 12 may include, for example, a rigid material such as a metal to reinforce a supporting force of the first support member BP1 and the second support member BP2, without being limited thereto. As an example, the plate 12 may include one or a combination of stainless steel (SUS), glass, ceramic, and metal, without being limited thereto. As an example, the plate 12 may be made of a plastic material including at least one of polycarbonate (PC), polyimide (PI), polyethylene naphthalate (PEN), and polyethylene terephthalate (PET). As an example, the plate 12 may be omitted depending on the design.

As an example, the first support member BP1 may be attached to an upper surface of the plate 12 through the third adhesive layer AD3.

As an example, the connection member (Bezel Bending Fixing Tape) 13 may be disposed on a lower surface of the plate 12. The connection member 13 may fix a bezel bent state. Embodiments are not limited thereto. As an example, the connection member 13 may be disposed on an upper surface of the plate 12, or may be omitted depending on the design.

The connection member 13 may be disposed between the second support member BP2 and the plate 12 to fix the bent portion of the display panel 100 to be in a position between the first area 1A and the second area 2A. The connection member 13 may be adhered to the plate 12 through the fourth adhesive layer AD4 and may be adhered to the second support member BP2 through the fifth adhesive layer AD5, without being limited thereto.

When the display panel 100 is bent in the bent area BA such that the pad of the display panel 100 is disposed on the lower surface of the display panel 100, that is, on the rear surface thereof, a restoring force to return the display panel 100 to its state before being bent may be applied to the display panel 100.

When the restoring force acts on the display panel 100, a lifting phenomenon that the pad of the bent portion of the display panel 100 is fixed but lifts off may occur.

The connection member 13 may be disposed between a front portion and the pad of the display panel 100 and may serve to fix the bent portion of the display panel 100 so as to be maintained at its bent shape.

As an example, the connection member 13 may be formed to have a constant thickness. As an example, the connection member 13 may be embodied as a double-sided tape with a strong adhesive force that may secure the pad and the front portion of the display panel 100 to each other. As an example, the fourth adhesive layer AD4 and/or the fifth adhesive layer AD5 may be omitted.

As an example, the connection member 13 may include at least one layer and may be made of at least one of OCA (Optical Clear Adhesive), OCR (Optical Clear Resin), or a pressure sensitive adhesive (PSA), without being limited thereto.

As an example, the connection member 13 may be present in a form of a foam tape or a foam pad with a shock absorbing function or a double-sided tape with conductivity, without being limited thereto. For example, the double-sided conductive tape may include an upper adhesive layer, a lower adhesive layer and a conductive layer between the upper adhesive layer and the lower adhesive layer, wherein each of the upper adhesive layer and the lower adhesive layer may include a conductive material.

The connection member 13 may be attached to the plate 12 through the fourth adhesive layer AD4. The plate 12 may include a metal material, without being limited thereto. Although not shown, as an example, the plate 12 may include an embossed layer in contact with the first support member BP1; a cushion layer disposed under the embossed layer and having a shock-relieving function; and a heat dissipation layer disposed under the cushion layer and having a heat dissipation function, without being limited thereto.

In the display device 1 shown in FIG. 2, the components may be stacked in the vertical direction (Z direction) and between the first area 1A and the second area 2A as follows.

For example, the bent reinforcement member 11 may be disposed on the back frame 30, the bent portion of the sealing layer 200 may be disposed on the reinforcement member 11, and the bent portion of the display panel 100 may be disposed on the bent portion of the sealing layer 200.

The sixth adhesive layer AD6 may be disposed on the bent portion of the display panel 100, and the second support member BP2 may be disposed on the sixth adhesive layer AD6, and the fifth adhesive layer AD5 may be disposed on the second support member BP2, and the connection member 13 may be disposed on the fifth adhesive layer AD5.

The fourth adhesive layer AD4 may be disposed on the connection member 13, the plate 12 may be disposed on the fourth adhesive layer AD4. The third adhesive layer AD3 may be disposed on the plate 12. The first support member BP1 may be disposed on the third adhesive layer AD3.

The second adhesive layer AD2 may be disposed on the first support member BP1, and a flat portion of the display panel 100 may be disposed on the second adhesive layer AD2.

The flat portion of the sealing layer 200 may be disposed on the flat portion of the display panel 100, the first adhesive layer AD1 may be disposed on the flat portion of the sealing layer 200, and the polarizing layer 14 may be disposed on the first adhesive layer AD1. The optical adhesive layer (Optical Clear Adhesive) 15 may be disposed on the polarization layer 14, and the cover member 20 may be disposed on the optical adhesive layer 15.

The cover member 20 may protect the display panel 100 from external shock and may transmit light emitted from the display panel 100 therethrough so that the image displayed from the display panel 100 is visible from an outside.

This cover member 20 may be made of a material which has impact resistance and light transparency, for example, may be made of any one of glass, reinforced glass, poly methyl methacrylate (PMMA), poly carbonate (PC), cycloolefin polymer (COP), polyethylene terephthalate (PET), polyimide (PI), or polyamide (PA). Embodiments of the present disclosure are not limited thereto.

The optical adhesive layer 15 may have a thickness of, for example, 100 to 300 μm, without being limited thereto. When the optical adhesive layer 15 has a thickness of 100 μm or smaller, the adhesive strength becomes weak, making it difficult to modularize the cover member 20 and the first and second support members BP1 and BP2. When the optical adhesive layer 15 has a thickness of 300 μm or greater, difficulty in folding the display device 1 may occur. Therefore, the optical adhesive layer 15 may have a thickness of 100 to 300 μm. Embodiments are not limited thereto. As an example, the optical adhesive layer 15 may have a thickness of out of the range of 100 to 300 μm.

The polarization layer 14 reduce or prevents a contrast ratio CR from decreasing due to external light. In the display device 1 according to the present disclosure, the display panel may be embodied as an OLED panel. In this case, when the display panel operates in a driving mode that displays an image, the polarizing layer 14 that blocks external light incident from the outside may be placed into a travel path of the light emitted through the display panel such that the contrast ratio is improved.

A single support member disposed in the first area 1A, the bent area BA, and the second area 2A may be cut away in the bent area BA such that the first support member BP1 is located on top of the plate 12 and under the display panel 100 in the first area 1A, while the second support member BP2 is located in the second area 2A including the rear surface of the display panel 100, without being limited thereto.

In this regard, the support member in the bent area BA is cut away such that a portion of the display panel 100 in the bent area BA is exposed. Then, the reinforcement member 11 and the display panel 100 are bent in the bent area BA and the connection member 13 are bonded to the second support member BP2 through the fifth adhesive layer AD5.

The reinforcement member 11 improves the deformation of the display panel 100 in the bent area BA. As an example, the reinforcement member 11 allows the display panel 100 to be bent at a constant curvature, without being limited thereto. As an example, the display panel 100 may be bent at varied curvatures. The reinforcement member 11 may be composed of a resin layer to compensate for the weakening of the rigidity due to the bending of the display panel 100 in the bent area BA, without being limited thereto. As an example, the reinforcement member 11 may be made of a polymer such as polyimide (PI) or polyethylene terephthalate (PET). When the reinforcement member 11 is embodied as a polymer film, the member 11 may have a modulus of about 1 to about 10 GPa. Embodiments of the present disclosure are not limited thereto.

In FIG. 2, the back frame 30 may include a metal, without being limited thereto. Accordingly, the back frame 30 made of the metal may accommodate therein the components including the display panel 100 disposed on the rear surface of the cover member 20, and protect the components.

Alternatively, as an example, the back frame 30 may include a plastic material such as resin with a shock absorbing function. In this case, when an impact is applied to the back frame 30 due to an external force above a certain pressure, the impact may be alleviated by the shock absorbing function of the plastic material.

Therefore, the cushioning effect of the back frame 30 may reduce or prevent cracks from occurring in the display panel 100 to protect the display panel 100.

In FIG. 2, the display device 1 may include a third area 3A excluding the bent area BA from the bezel area BZA. The third area 3A may adjust a size of the bezel area BZA. Accordingly, the third area 3A may be referred to as ‘system space’. Therefore, in the display device 1 according to an exemplary embodiment of the present disclosure, the size of the bezel area BZA may be determined based on the third area 3A. The size of the third area 3A may be adjusted based on a thickness of the sealing layer 200 and a thickness of the reinforcement member 11. For example, when the sealing layer 200 may be disposed to extend into the bent area BA, the size of the third area 3A may be reduced. In this case, the size of the bezel area BZA may be reduced.

The sealing layer 200 may be disposed on top of the display panel 100 in the first area 1A, may be disposed on an outer surface of the display panel 100 in the bent area BA, and may be disposed under the display panel 100 in the second area 2A.

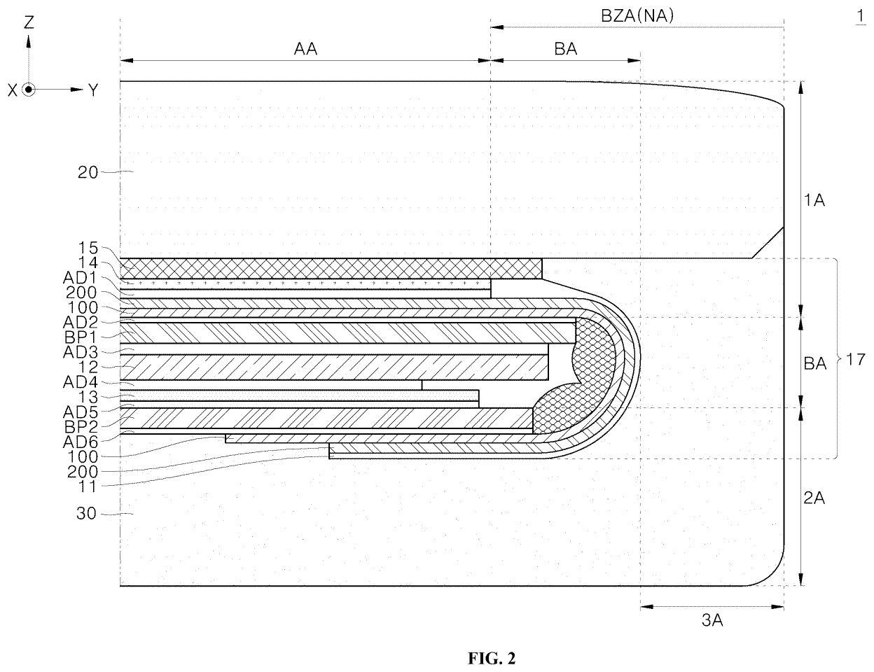

The sealing layer 200 disposed to extend from the first area 1A into the second area 2A through the bent area BA may have a constant thickness as shown in FIG. 3. FIG. 3 is a diagram showing an example in which the sealing layer on the display panel has a constant thickness according to an exemplary embodiment of the present disclosure. As shown in FIG. 3, the sealing layer 200 may have a constant thickness across the display area AA, the bent area BA, and the non-display area NA. The sealing layer 200 may have a constant thickness across the first area 1A, the bent area BA, and the second area 2A.

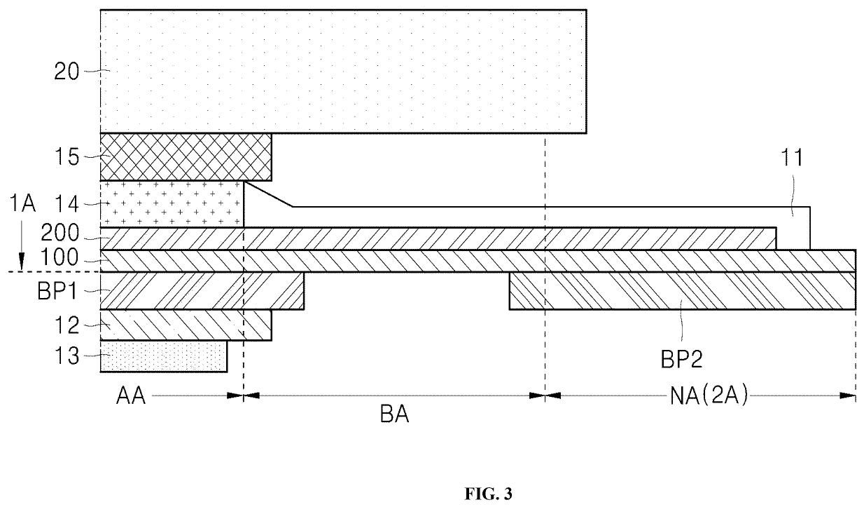

A sealing layer 200-1 according to another exemplary embodiment of the present disclosure may have different thicknesses in the first area 1A, the bent area BA, and the second area 2A, as shown in FIG. 4. FIG. 4 is a diagram showing an example in which the sealing layer 200-1 is thicker in the second area 2A than in the first area 1A according to another exemplary embodiment of the present disclosure. For example, the sealing layer 200-1 may have a greater thickness in the second area 2A than that in the first area 1A, as shown in FIG. 4. The sealing layer 200-1 may have an increasingly larger thickness as it extends from the first area 1A to the second area 2A through the bent area BA.

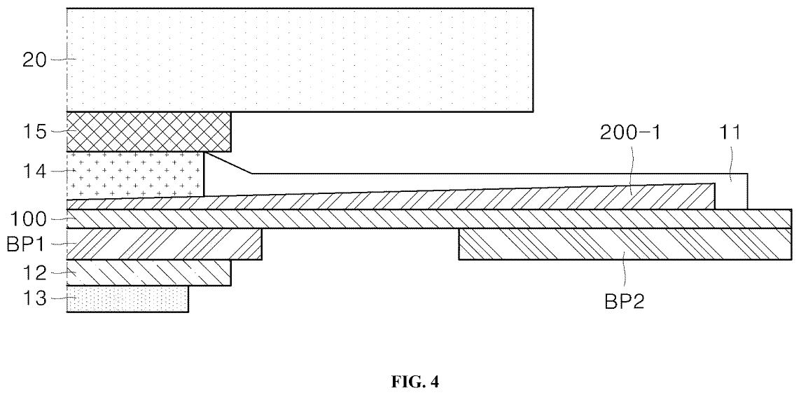

As shown in FIG. 5, a sealing layer 200-2 according to still another exemplary embodiment of the present disclosure may have different thicknesses in the first area 1A, bent area BA, and the second area 2A. FIG. 5 is a diagram showing an example in which the scaling layer 200-2 is thicker in the first area 1A than in the second area 2A according to still another exemplary embodiment of the present disclosure. For example, the sealing layer 200-2 may have a greater thickness in the first area 1A than that in the second area 2A, as shown in FIG. 5. The sealing layer 200-2 may have a thickness that gradually becomes smaller as it extends from the first area 1A to the second area 2A through the bent area BA.

Each of the scaling layers 200, 200-1, and 200-2 as shown in FIGS. 2 to 5 may include an organic material, without being limited thereto.

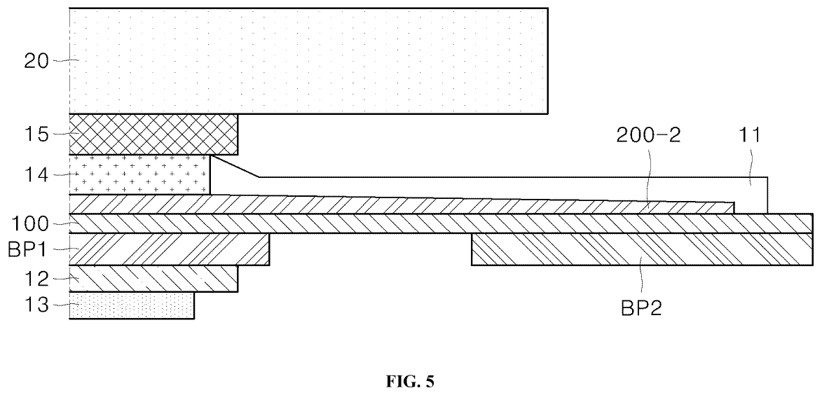

As shown in FIG. 6, the display panel 100 may include an encapsulation layer ENCAP and a touch layer TL on the encapsulation layer ENCAP.

As shown in FIG. 6, the scaling layer 200 may be disposed on top of the touch layer TL on the encapsulation layer ENCAP. In this regard, the encapsulation layer ENCAP may include a first encapsulation layer PAS1 embodied as an inorganic film, a second encapsulation layer PCL embodied as an organic film and disposed on the first encapsulation layer PAS1, and a third encapsulation layer PAS2 disposed on the second encapsulation layer PCL and embodied as an organic film. Embodiments are not limited thereto. As an example, each of the first encapsulation layer PAS1, the second encapsulation layer PCL and the third encapsulation layer PAS2 may be embodied as an organic film, an inorganic film or a combination thereof.

FIG. 6 is a cross-sectional view of a display area including a touch structure under a sealing layer 200 according to an exemplary embodiment of the present disclosure.

Referring to FIG. 6, a substrate SUB may include a first substrate SUB1, an interlayer insulating film IPD, and a second substrate SUB2. The interlayer insulating film IPD may be located between the first substrate SUB1 and the second substrate SUB2. When the substrate SUB is composed of the first substrate SUB1, the interlayer insulating film IPD, and the second substrate SUB2, this configuration may reduce or prevent moisture penetration. For example, each of the first substrate SUB1 and the second substrate SUB2 may be embodied as a polyimide (PI) substrate. The first substrate SUB1 may be referred to as a first PI substrate, and the second substrate SUB2 may be referred to as a second PI substrate. Embodiments are not limited thereto. As an example, the substrate SUB may include a single substrate or multiple substrates embodied as various organic or inorganic materials.

On the substrate SUB, various patterns ACT, SD1, and GATE to constitute a transistor such as a driving transistor DRT, etc., various insulating films MBUF, ABUF1, ABUF2, GI, ILD1, ILD2, and PAS0, and various metal patterns TM, GM, ML1, and ML2 may be disposed.

A multi-buffer layer MBUF may be disposed on the second substrate SUB2, and a first active buffer layer ABUF1 may be disposed on the multi-buffer layer MBUF, without being limited thereto.

A first metal layer ML1 and/or a second metal layer ML2 may be disposed on the first active buffer layer ABUF1. In this regard, each of the first metal layer ML1 and the second metal layer ML2 may act as a light shield layer LS that shields light. As an example, the first metal layer ML1 and/or the second metal layer ML2 may be omitted depending on the design,

A second active buffer layer ABUF2 may be disposed on the first metal layer ML1 and the second metal layer ML2. An active layer ACT of the driving transistor DRT may be disposed on the second active buffer layer ABUF2.

A gate insulating film GI may be disposed so as to cover the active layer ACT.

A gate electrode GATE of the driving transistor DRT may be disposed on the gate insulating film GI. In this regard, a gate material layer GM together with the gate electrode GATE of the driving transistor DRT may be disposed on the gate insulating film GI in a position different from a formation position of the driving transistor DRT.

A first interlayer insulating film ILD1 may be disposed to cover the gate electrode GATE and the gate material layer GM. A metal pattern TM may be disposed on the first interlayer insulating film ILD1. The metal pattern TM may be located at a location different from the formation location of the driving transistor DRT. A second interlayer insulating film ILD2 may be disposed to cover the metal pattern TM on the first interlayer insulating film ILD1.

Two first source-drain electrode patterns SD1 may be disposed on the second interlayer insulating film ILD2. One of the two first source-drain electrode patterns SD1 may act as a source node of the driving transistor DRT, and the other thereof may act as a drain node of the driving transistor DRT.

The two first source-drain electrode patterns SD1 may be electrically connected to one side and the other side of the active layer ACT, respectively, via contact holes extending through the second interlayer insulating film ILD2, the first interlayer insulating film ILD1, and the gate insulating film GI.

In one example, referring to FIG. 6, the second interlayer insulating film ILD2 may include a (2-1)-th interlayer insulating film ILD2-1 and a (2-2)-th interlayer insulating film ID22-2, without being limited thereto. The (2-1)-th interlayer insulating film ILD2-1 may be positioned so as to cover the metal pattern TM. The (2-2)-th interlayer insulating film ILD2-2 may be located on the (2-1)-th interlayer insulating film ILD2-1.

A portion of the active layer ACT that overlaps the gate electrode GATE acts as a channel area. One of the two first source-drain electrode patterns SD1 may be connected to one side of the channel area of the active layer ACT, and the other of the two first source-drain electrode patterns SD1 may be connected the other side of the channel area of the active layer ACT.

A passivation layer PAS0 may be disposed to cover the two first source-drain electrode patterns SD1. A planarization layer PLN may be disposed on the passivation layer PAS0. The planarization layer PLN may include a first planarization layer PLN1 and a second planarization layer PLN2, or may include a single planarization layer or more than two planarization layers, without being limited thereto.

The first planarization layer PLN1 may be disposed on the passivation layer PAS0.

A second source-drain electrode pattern SD2 may be disposed on the first planarization layer PLN1. The second source-drain electrode pattern SD2 may be connected to one of the two first source-drain electrode patterns SD1 via a contact hole extending through the first planarization layer PLN1.

A second planarization layer PLN2 may be disposed so as to cover the second source-drain electrode pattern SD2. A light-emitting element ED may be disposed on the second planarization layer PLN2.

Referring to a stack structure of the light-emitting element ED, an anode electrode AE may be disposed on the second planarization layer PLN2. The anode electrode AE may be electrically connected to the second source-drain electrode pattern SD2 via a contact hole extending through the second planarization layer PLN2.

A bank BANK may be disposed to cover a portion of the anode electrode AE. A portion of the bank BANK corresponding to a light-emitting area EA of the sub-pixel SP may be open.

A portion of the anode electrode AE may be exposed through an opening of the bank BANK. A light-emitting layer EL may be located on a side surface of the bank BANK adjacent to the opening of the bank BANK, without being limited thereto. As an example, the light-emitting layer EL may be further located on a portion of av top surface of the bank BANK. An entirety or a portion of the light-emitting layer EL may be located between adjacent portions of the bank BANK.

In the opening of the bank BANK, the light-emitting layer EL may contact the anode electrode AE. A cathode electrode CE may be disposed on the light-emitting layer EL.

The light-emitting element ED may be composed of the anode electrode AE, the light-emitting layer EL, and the cathode electrode CE. The light-emitting layer EL may include an organic film.

The encapsulation layer ENCAP may be disposed on the light-emitting element ED as described above.

The encapsulation layer ENCAP may have a single-layer structure or a multi-layer structure. For example, as shown in FIG. 6, the encapsulation layer ENCAP may include the first encapsulation layer PAS1, the second encapsulation layer PCL, and the third encapsulation layer PAS2.

For example, each of the first encapsulation layer PAS1 and the third encapsulation layer PAS2 may be embodied as an inorganic layer, and the second encapsulation layer PCL may be embodied as an organic layer. Among the first encapsulation layer PAS1, the second encapsulation layer PCL, and the third encapsulation layer PAS2, the second encapsulation layer PCL may be the thickest, without being limited thereto. According to this exemplary configuration, the second encapsulation layer PCL may serve as a planarization layer. The first encapsulation layer PAS1 may be referred to as a first inorganic encapsulation layer, the second encapsulation layer PCL may be referred to as an organic encapsulation layer, and the third encapsulation layer PAS2 may be referred to as a second inorganic encapsulation layer.

The first encapsulation layer PAS1 may be disposed on the cathode electrode CE and may be a layer among the first encapsulation layer PAS1, the second encapsulation layer PCL, and the third encapsulation layer PAS2 which may be disposed closest to the light-emitting element ED. The first encapsulation layer PAS1 may be made of an inorganic insulating material which may be subjected to low-temperature deposition, without being limited thereto. For example, the first encapsulation layer PAS1 may be made of silicon nitride (SiNₓ), silicon oxide (SiOₓ), silicon oxynitride (SiON), or aluminum oxide (Al₂O₃), without being limited thereto. Since the first encapsulation layer PAS1 is deposited in a low-temperature atmosphere, the first encapsulation layer PAS1 may reduce or prevent the light-emitting layer EL which contains an organic material vulnerable to a high-temperature atmosphere from being damaged during the deposition process.

The second encapsulation layer PCL may be formed to have a smaller area size than that of the first encapsulation layer PAS1, without being limited thereto. In this case, the second encapsulation layer PCL may be formed not to cover both opposing ends of the first encapsulation layer PAS1 so as to be exposed. The second encapsulation layer PCL may serve as a shock-absorbing layer to relieve stress between the layers, for example, due to the bending of the display device 1 and may serve to enhance planarization performance. For example, the second encapsulation layer PCL may be made of acrylic resin, epoxy resin, polyimide, polyethylene, or silicon oxycarbon (SiOC), or may be made of other in organic or organic insulating material. For example, the second encapsulation layer PCL may be formed in an inkjet scheme.

The third encapsulation layer PAS2 may be formed on the substrate SUB on which the second encapsulation layer PCL has been formed so as to cover upper and side surfaces of each of the second encapsulation layer PCL and the first encapsulation layer PAS1. The third encapsulation layer PAS2 may reduce, minimize or block external moisture or oxygen from penetrating into the first encapsulation layer PAS1 and the second encapsulation layer PCL. For example, the third encapsulation layer PAS2 may be made of an inorganic insulating material such as silicon nitride (SiNₓ), silicon oxide (SiOₓ), silicon oxynitride (SiON), or aluminum oxide (Al₂O₃), without being limited thereto.

Referring to FIG. 6, when a touch sensor TS is built into the display panel 100, the touch layer TL including the touch sensor TS may be disposed on the encapsulation layer ENCAP, without being limited thereto. As an example, the touch sensor TS may be omitted depending on the design. A detailed description of the touch sensor structure is as follows.

A touch buffer film T-BUF may be disposed on the third encapsulation layer PAS2 of the encapsulation layer ENCAP. The touch sensor TS and a touch interlayer insulating film T-ILD may be disposed on the touch buffer film T-BUF. A touch protective film PAC may be disposed on the touch sensor TS and the touch interlayer insulating film T-ILD. The scaling layer 200 may be disposed on the touch protective film PAC.

The touch sensor TS may include touch sensor metals TSM and a bridge metal BRG located in different layers.

The touch interlayer insulating film T-ILD may be disposed between each of the touch sensor metals TSM and the bridge metal BRG.

For example, the touch sensor metals TSM may include a first touch sensor metal TSM, a second touch sensor metal TSM, and a third touch sensor metal TSM disposed adjacent to each other. The third touch sensor metal TSM may be disposed between the first touch sensor metal TSM and the second touch sensor metal TSM. When the first touch sensor metal TSM and the second touch sensor metal TSM must be electrically connected to each other, the first touch sensor metal TSM and the second touch sensor metal TSM may be electrically connected to each other via the bridge metal BRG positioned at a different layer from the layer of the first touch sensor metal TSM and the second touch sensor metal TSM. The bridge metal BRG may be insulated from the third touch sensor metal TSM by the touch interlayer insulating film T-ILD.

When the touch sensor TS is formed in the display panel 100, chemicals (developer or etchant, etc.) used in the process may flow into the underlying layer, or moisture may flow into the underlying layer from the outside. Thus, when the touch sensor TS is disposed on the touch buffer film T-BUF, the chemicals or moisture may be reduced or prevented from penetrating into the light-emitting layer EL containing the organic material during the manufacturing process of the touch sensor TS. Accordingly, the touch buffer film T-BUF may mitigate or prevent the light-emitting layer EL which is vulnerable to the chemicals or moisture from being damaged.

The touch buffer film T-BUF may be made of an organic insulating material with can be deposited at low temperatures below a certain temperature (e.g., 100 degrees C.) to reduce or prevent the damage to the light-emitting layer EL which contains the organic material vulnerable to high temperatures, and which has a low dielectric constant of 1 to 3, without being limited thereto. For example, the touch buffer film T-BUF may be made of an acryl-based, epoxy-based, or siloxan-based material. As the display device 1 is bent, the encapsulation layer ENCAP may be damaged and the touch sensor metal located on the touch buffer film T-BUF may be broken. In the present exemplary embodiment, even when the display device 1 is bent, the touch buffer film T-BUF which is made of the organic insulating material and has a planarization performance may reduce or prevent the damage to the encapsulation layer ENCAP and/or may mitigate or prevent the metals TSM and BRG constituting the touch sensor TS from being broken.

The touch protective film PAC may be disposed on the touch sensor TS and the touch interlayer insulating film T-ILD. The touch protective film PAC may be disposed to cover the touch sensor TS. The touch protective film PAC may be embodied as an organic insulating film, without being limited thereto. The sealing layer 200 may be disposed on the touch protective film PAC, without being limited thereto. In this regard, the sealing layer 200 may be made of an insulating material such as acryl resin, epoxy resin, polyimide, polyethylene, or silicon oxycarbon (SiOC) to reduce or prevent infiltration of moisture from the outside.

In one example, the sealing layer 200 according to an exemplary embodiment of the present disclosure may be formed on the display panel 100 using a manufacturing apparatus. The manufacturing apparatus may include a resin application valve (jet valve) and a resin application nozzle, without being limited thereto. Accordingly, a formation process of the sealing layer 200 may be carried out while a chip on film (COF), a flexible printed circuit board (FPCB), and/or a FPC protective film (FPC Top Liner) have been disposed, without being limited thereto.

As an example, the sealing layer 200 may be formed by applying a mixed solution of a resin component and aluminum (Al) nanoparticles through the application nozzle while the resin application valve has been located at an end of the display panel 100, without being limited thereto.

As an example, the resin component is a material used to form the reinforcement member 11 as a micro coating layer (MCL), without being limited thereto. In the mixed solution of the resin component and the aluminum nanoparticles, the aluminum nanoparticles may correspond to a thickness of 10 to 30 nanometers nm and may have a content of 10 vol %. The mixed solution may be applied to an overall thickness of 60 nanometers (nm). In this regard, vol % refers to a physical volume unit and represents a volume proportion of a material with respect to 100% as a unit volume. Therefore, the fact that the content of the aluminum nanoparticles is 10 vol % indicates that the aluminum nanoparticles occupy a volume proportion of 10% in the 100% volume of the mixed solution. Embodiments are not limited thereto. As an example, the thickness and content of the aluminum nanoparticles, the overall thickness of the mixed solution may be adjusted in various ways.

The sealing layer 200 formed through the above-described process includes the aluminum (Al) nanoparticles. Thus, when the ultraviolet (UV) rays are irradiated thereto, the ultraviolet rays may be reflected from the aluminum nanoparticles.

In this regard, the aluminum nanoparticles are found to have higher ultraviolet ray reflectance than those of other metal nanoparticles. The aluminum nanoparticles are found to have the ultraviolet ray reflectance of 0.9 when a wavelength λ of the ultraviolet rays is 350 nanometers (nm). Therefore, it may be identified that aluminum has the higher UV ray reflectance than those of other metals when ultraviolet rays of the same wavelength are irradiated thereto. Embodiments are not limited thereto. As an example, the sealing layer 200 may include no aluminum (Al) nanoparticles.

The mixed solution of the resin component and the aluminum nanoparticles ma reflect 90% of the ultraviolet rays with a wavelength λ of 350 nanometers (nm) irradiated to the sealing layer 200 due to the high UV-ray reflectance of the aluminum nanoparticles.

As an example, the mixed solution of the resin component and the aluminum nanoparticles as a composite material is applied to a thickness of 60 nanometers (nm) on the reinforcement member 11 or the display panel 100. In this case, when the aluminum nanoparticles are deposited in the mixed solution at 10 vol %, the reflectance and modulus values are found to be high. When the aluminum nanoparticles are deposited to a thickness equal or smaller than 6 nanometers (nm) corresponding to 10 vol % out of the total thickness of 60 nanometers (nm) of the sealing layer 200, the ultraviolet ray reflectance thereof is about 90%, and the modulus thereof is approximately 1,625 megapascals (MPa).

As described above, the reinforcement member 11 and the sealing layer 200 are dispose on the outer surface of the bent portion of the display panel 100 in the bent area BA. Thus, when the ultraviolet rays are irradiated thereto, the ultraviolet rays are reflected from the metal nanoparticles to reduce or prevent panel cracks and damage.

Furthermore, during manufacturing of the display panel 100, an amount of the ultraviolet ray irradiation may be locally controlled based on an amount of deposition of the metal nanoparticles included in the sealing layer 200 in the bent area BA which is vulnerable to the ultraviolet ray irradiation.

Furthermore, during manufacturing of the display panel 100, the ultraviolet rays may be reflected from the metal nanoparticles included in the sealing layer 200, thereby supplementing compression rigidity of the bent area BA of the display panel 100.

In one example, a driving integrated circuit may be disposed on the opposite side of the pad of the display panel 100.

As an example, the driving integrated circuit may be mounted in the display panel 100 in a chip bonding process or a surface mounting process, without being limited thereto. Based on the bent state, the driving integrated circuit may be disposed under the display panel 100. For example, the driving integrated circuit may be disposed under the pad.

In this case, a flexible printed circuit board (not shown) may be disposed between the pad and the driving integrated circuit, such that the driving integrated circuit may be located on a rear surface of the flexible printed circuit board (FPCB), without being limited thereto.

The driving integrated circuit generates a data signal and/or a gate control signal based on image data and a timing synchronization signal supplied from an external host driving system. The driving integrated circuit may supply a data signal to a data line of each pixel and supply the gate control signal to a gate driver circuit (not shown) through the pad.

The driving integrated circuit may be mounted in a chip mounting area defined in the display panel 100 and may be electrically connected to the pad, and may be connected to a signal line of the gate driver circuit and the pixel array disposed on the display panel 100.

Since the driving integrated circuit generates considerable heat, it is advantageous to effectively dissipate the heat from the driving integrated circuit. As an example, the heat from the driving integrated circuit may be primarily dissipated by a support plate.

The pad may be disposed at one side of the display panel 100 to which the driving integrated circuit is connected to. The pad may be electrically connected to the flexible printed circuit board on which a circuit board has been mounted on the rear surface of the display panel 100.

One side of the flexible printed circuit board may be electrically connected to the pad provided at one side of the display panel 100, for example, in a film attachment process using a conductive adhesive layer, without being limited thereto. The flexible printed circuit board may be located on the rear surface of the display panel 100.

In this case, the conductive adhesive layer may be embodied as an anisotropic conductive film (ACF) by way of example.

The circuit board may provide the image data and the timing synchronization signal supplied from the host driving system to the driving integrated circuit, and may provide voltage necessary to drive each of the pixel array, the gate driver circuit, and the driving integrated circuit.

The flexible printed circuit board having one side connected to the display panel 100 may be formed to extend such that the flexible printed circuit board along with the display panel 100 is bent toward a rear surface of the display panel 100.

The flexible printed circuit board extending from one side thereof connected to the display panel 100 may be located on a portion of the rear surface of the display panel 100 that is not covered with the pad of the display panel 100.

Accordingly, at least a portion of the flexible printed circuit board may contact the rear surface of the display panel 100.

The display device 1 according to an exemplary embodiment of the present disclosure refers to a display device having flexibility, and may refer to a bendable display device, a rollable display device, an unbreakable display device, and a foldable display device, without being limited thereto.

As an example, the driving integrated circuit may be embodied as a thin film transistor (TFT) in the non-display area NA. This driving integrated circuit may be referred to as gate-in-panel (GIP) circuit. The GIP circuit GIP may include a gate driver of a GIP structure. In this regard, the gate driver may be embodied as a bottom gate type thin film transistor (BG-T), and a source and drain metal film of a bridge wiring may extend to be connected to a drain electrode of the BG type thin film transistor, without being limited thereto.

Furthermore, some components, such as a data driver IC may be mounted on a separate printed circuit board and may be coupled to a connection interface (pad/bump, pin, etc.) disposed in the non-display area NA using a circuit film such as a FPCB (flexible printed circuit board), COF (chip-on-film), TCP (tape-carrier-package), etc. The non-display area NA together with the connection interface may be bent so that the printed circuit board (COF, PCB, etc.) may be located on the rear surface or back surface of the display device 1.

The display device 1 according to the present disclosure may include various additional elements for generating various signals, or for driving the pixels PX within the display area. The additional elements for driving the pixels may include an inverter circuit, a multiplexer, an electrostatic discharge circuit, etc, without being limited thereto. The display device 1 according to the present disclosure may include additional elements associated with functions other than the pixel operation. For example, the display device 1 according to the present disclosure includes additional elements that provide a touch detection function, a user authentication function (e.g., fingerprint recognition), a multi-level pressure detection function, a tactile feedback function, etc. The above-mentioned additional elements may be located in the non-display area NA and/or in an external circuit connected to the connection interface.

Several portions of the display device 1 according to the present disclosure may be bent along a bend line. The bend line may extend horizontally, vertically, or diagonally. Accordingly, the display device 1 according to an exemplary embodiment of the present disclosure may be bent in a combination of horizontal, vertical, and diagonal directions, based on a required design.

One or more edges of the display device 1 according to the present disclosure may be bent along a bend line so as to be away from a central portion. The bend line may be located close to an edge of the display device 1, but may also extend across the central portion or extend diagonally from one or more corners of the display device 1. This structure may enable the display device 1 to be a foldable display device or a display device in which an image is displayed on each of both folded surfaces.

Since one or more portions of the display device 1 may be curved, the display device 1 according to the present disclosure may include a substantially flat portion and a curved portion. One portion of the display device 1 may be referred to as a substantially flat area. One portion of the display device 1 may be bent at a predetermined angle, and this portion may be referred to as a bent area or a curvature area. The curvature area includes a curved section that is actually bent at a predetermined curved radius.

The term “substantially flat” also includes a portion that is not perfectly flat. For example, a concave central portion and a convex central portion may also be described as a substantially flat portion in some embodiments. One or more curved portions may exist next to the concave central portion or the convex central portion and may be bent inwardly or outwardly along the bend line at an angle relative to a curved axis. The curvature radius of the curvature area is smaller than the curvature radius of the flat area. In other words, the term “substantially flat portion” refers to a portion that has a smaller curvature than that of a section adjacent thereto. Also, the term “substantially flat portion” also includes a portion that is perfectly flat

Depending on a location of the bend line, as an example, a portion on one side of the bend line is located toward a center of the display device 1, while a portion on the other side of the bend line is located toward the edge of the display device 1. The portion disposed toward the center of the display device 1 may be referred to as a central portion, and the portion disposed toward the edge of the display device 1 may be referred to as an edge portion. Although not always the case, the central portion of the display device 1 may be substantially flat and the edge portions may be a curved portion. The substantially flat portion may be located in the edge portion. In some shapes of the display device 1, the curved section may lie between two substantially flat portions.

When the non-display area NA is bent, the non-display area NA may be invisible or only minimally visible to a viewer in front of the display device 1. A portion of the non-display area NA visible to the viewer in front of the display device 1 may be covered with the bezel. The bezel may be a stand-alone structure, or may be formed as a housing or a suitable element. The portion of the non-display area NA visible to the viewer in front of the display device 1 may be hidden under an opaque mask layer such as black ink (e.g., a polymer filled with carbon black). This opaque mask layer may be provided on various layers (touch sensor layer, polarizing layer, cover layer, etc.) included in the display device 1.

In some exemplary embodiments, the curved portion of the display device 1 may include a display area capable of displaying an image. As an example, the bend line may be disposed within the display area so that at least some pixels of the display area are included in the curved portion. Embodiments are not limited thereto. As an example, the curved portion of the display device 1 may not include a display area capable of displaying an image.

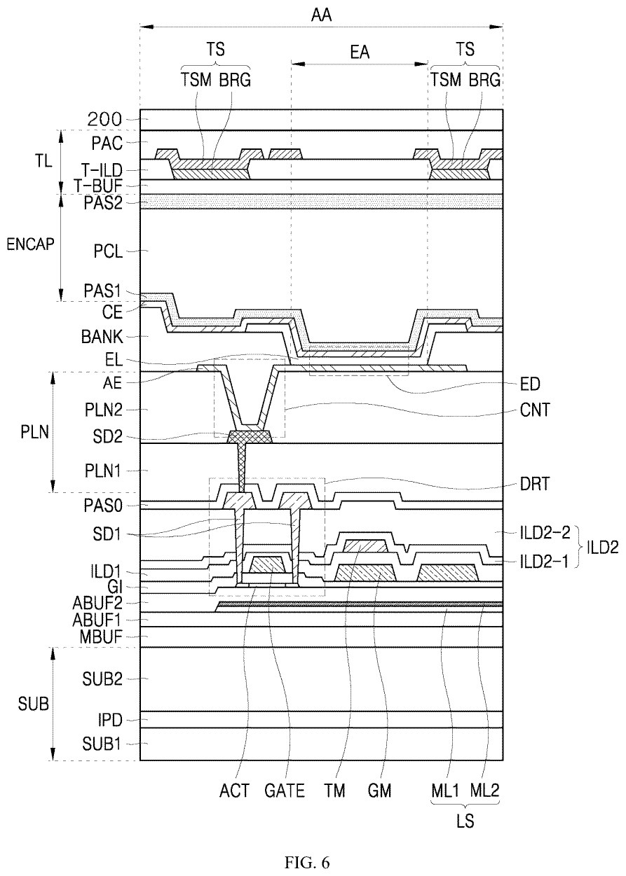

FIGS. 7 to 9 are diagrams showing examples in which a touch structure is applied to a sealing layer on a display panel according to an exemplary embodiment of the present disclosure.

Referring to FIG. 7, the scaling layer 200 according to an exemplary embodiment of the present disclosure may be disposed to have a constant thickness, and the reinforcement member 11 may be disposed to cover top and side surfaces of the sealing layer 200.

In this regard, the sealing layer 200 may contain a touch structure therein. The touch structure may include the first inorganic encapsulation layer PAS1, the organic encapsulation layer PCL disposed on the first inorganic encapsulation layer PAS1, the second inorganic encapsulation layer PAS2 disposed on the organic encapsulation layer PCL, the touch buffer film T-BUF disposed on the second inorganic encapsulation layer PAS2, the touch interlayer insulating film T-ILD disposed on the touch buffer film T-BUF, and the touch protective film PAC disposed on the touch interlayer insulating film T-ILD. Embodiments are not limited thereto. As an example, at least one of the above-mentioned components may be omitted, and/or one or more additional components may be further included.

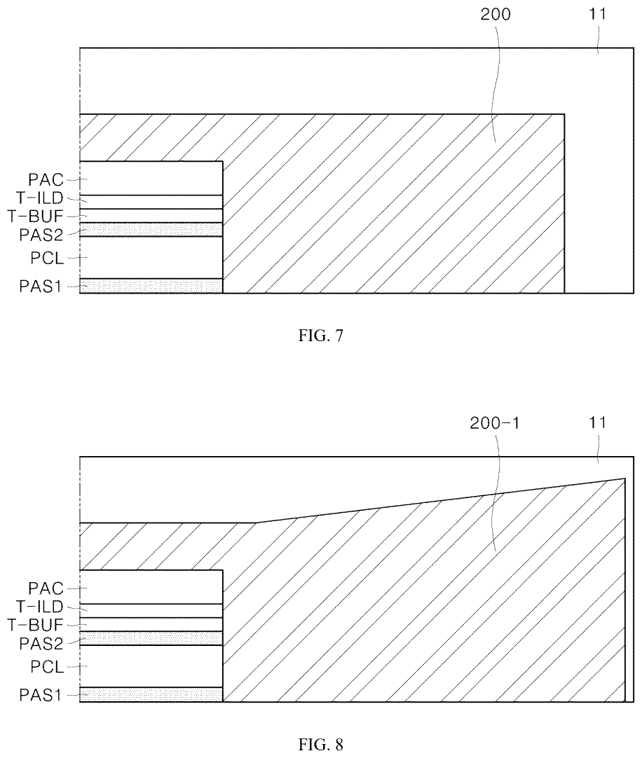

Referring to FIG. 8, the sealing layer 200-1 according to an exemplary embodiment of the present disclosure may have a shape in which a thickness gradually increases as the sealing layer extends from one side to the other side. The reinforcement member 11 may be disposed to cover top and side surfaces of the sealing layer 200-1.

In this regard, the sealing layer 200-1 may contain the touch structure therein. The touch structure may include the first inorganic encapsulation layer PAS1, the organic encapsulation layer PCL disposed on the first inorganic encapsulation layer PAS1, the second inorganic encapsulation layer PAS2 disposed on the organic encapsulation layer PCL, the touch buffer film T-BUF disposed on the second inorganic encapsulation layer PAS2, the touch interlayer insulating film T-ILD disposed on the touch buffer film T-BUF, and the touch protective film PAC disposed on the touch interlayer insulating film T-ILD.

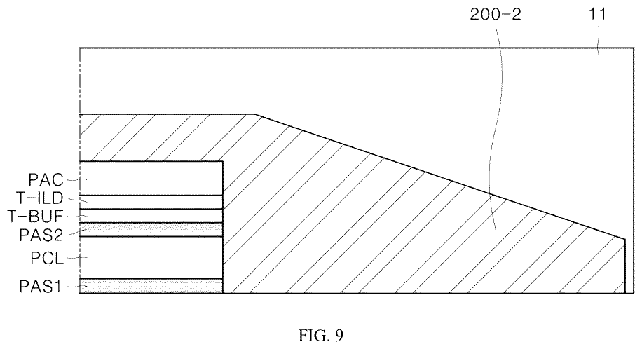

Referring to FIG. 9, the sealing layer 200-2 according to an exemplary embodiment of the present disclosure may have a shape in which a thickness gradually decreases as the sealing layer extends from one side to the other side. The reinforcement member 11 may be disposed to cover top and side surfaces of the sealing layer 200-2.

In this regard, the sealing layer 200-2 may contain the touch structure therein. The touch structure may include the first inorganic encapsulation layer PAS1, the organic encapsulation layer PCL disposed on the first inorganic encapsulation layer PAS1, the second inorganic encapsulation layer PAS2 disposed on the organic encapsulation layer PCL, the touch buffer film T-BUF disposed on the second inorganic encapsulation layer PAS2, the touch interlayer insulating film T-ILD disposed on the touch buffer film T-BUF, and the touch protective film PAC disposed on the touch interlayer insulating film T-ILD.

As an example, each of the sealing layers 200, 200-1, and 200-2 as shown in FIGS. 7 to 9 may include the metal nanoparticles. The metal nanoparticles include, for example, aluminum (Al) nanoparticles. Embodiments art not limited thereto. As an example, each of the sealing layers 200, 200-1, and 200-2 as shown in FIGS. 7 to 9 may include the metal nanoparticles other than aluminum (Al) nanoparticles. As an example, each of the sealing layers 200, 200-1, and 200-2 as shown in FIGS. 7 to 9 may include no metal nanoparticles.

Each of the sealing layers 200, 200-1, and 200-2 may be disposed between the display panel 100 and the reinforcement member 11. In this case, when the reinforcement member 11 is embodied as the micro coating layer (MCL), each of the sealing layers 200, 200-1, and 200-2 may be formed by applying the mixed solution of a component of the micro coating layer (MCL) and the aluminum (Al) nanoparticles. In this regard, the component of the micro coating layer (MCL) may include an acryl-based resin, without being limited thereto.

Each of the sealing layers 200, 200-1, and 200-2 may be applied on the display panel 100. In this case, when the ultraviolet rays (UV) are irradiated thereto, the amount of the ultraviolet rays irradiated to the bent area BA of the display panel 100 may be reduced, and the rigidity of a local area near the bent area BA of the display panel 100 may be strengthened.

Furthermore, when the ultraviolet rays (UV) are irradiated thereto, the damage to the vulnerable area of the display module 17 may be reduced by 10% compared to a conventional case, and thus the lifespan of the display panel 100 may be improved.

The metal nanoparticles included in each of the sealing layers 200, 200-1, and 200-2 disposed between the display panel 100 and the reinforcement member 11 may be applied to a thickness of 10 to 30 nanometers (nm), or to a thickness smaller than 10 nanometers (nm) or greater than 30 nanometers (nm).

The sealing layer 200 and the reinforcement member 11 may be applied on the display panel 100, for example, so as to have a length of 2.6 millimeters (mm) and a thickness of 60 micrometers (μm).

Each of the sealing layer 200, 200-1, and 200-2 together with the display panel 100 and the reinforcement member 11 may be bent in the bent area BA and thus may be disposed under the bent portion of the display panel 100 and extend horizontally in the second area 2A, a bent portion of each of the sealing layer 200, 200-1, and 200-2 may have, for example, a length of about 1.428 millimeters (mm). The length of the bent portion of each of the sealing layers 200, 200-1, and 200-2 according to an exemplary embodiment of the present disclosure is not limited thereto and may vary based on a model.

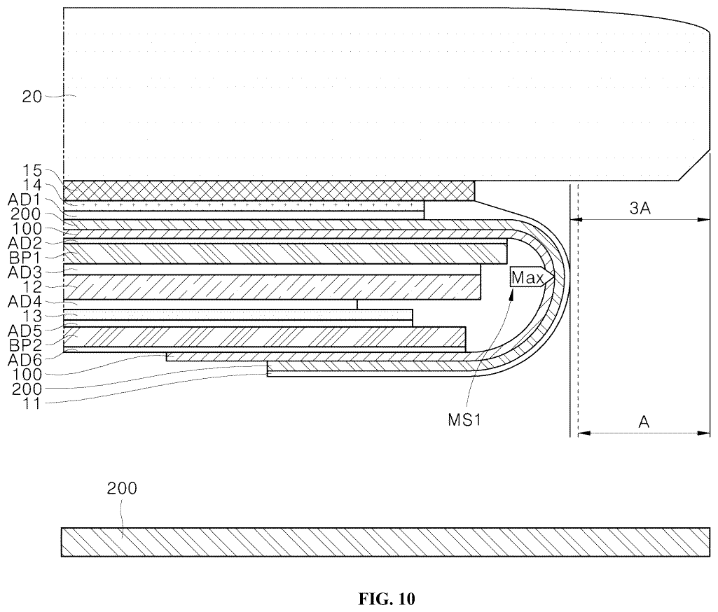

FIGS. 10 to 12 are diagrams showing examples in which a system space changes based on a change in the thickness of the sealing layer according to an exemplary embodiment of the present disclosure.

Referring to FIG. 10, when the sealing layer 200 according to an exemplary embodiment of the present disclosure has a constant thickness across the first area 1A, the bent area BA, and the second area 2A, the third area 3A may be changed to a first changed area A. A size of the first changed area A is smaller than a size of the third area 3A. When the scaling layer 200 extends from the display area AA into the bent area BA, the system space A of the display device 1 may be further reduced, and accordingly, the bezel area BAZ becomes smaller.

In this case, a thickness of the reinforcement member 11 disposed on the outer surface of the sealing layer 200 in the bent area BA may be reduced by about 32%.

Furthermore, a first maximum strain (MS1) value of a source-drain metal layer in the bent area BA may be improved by about 16% compared to a conventional case.

Accordingly, the crack risk in the bent area BA of the display device 1 may be reduced.

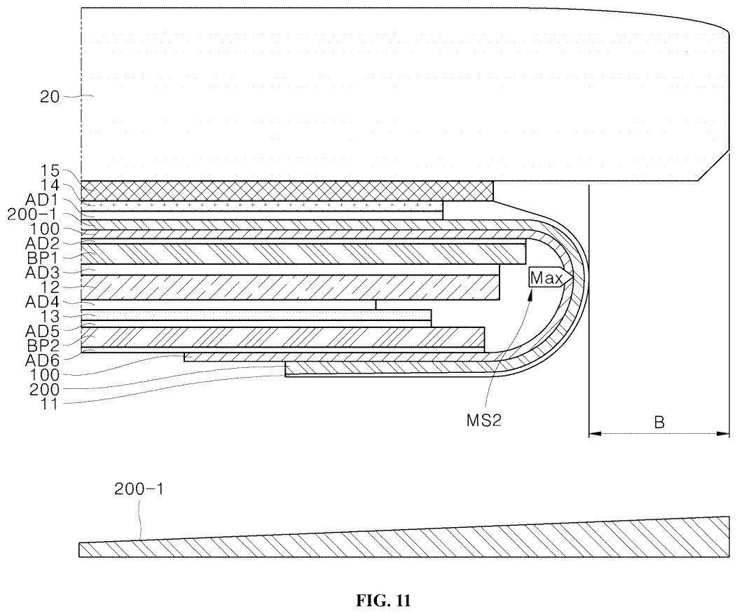

Referring to FIG. 11, when the thickness of the sealing layer 200-1 according to another exemplary embodiment of the present disclosure becomes increasingly larger as it extends from the first area 1A into the second area 2A through the bent area BA, the third area 3A may be changed to a second changed area B. A size of the second changed area B is smaller than the size of the third area 3A. When the sealing layer 200-1 is increasingly thicker as it extends from the display area AA into the bent area BA, the system space B of the display device 1 may be further reduced, and accordingly, the bezel area BAZ may be further reduced.

In this case, a second maximum strain (MS2) value of the source-drain metal layer in the bent area BA may be improved by about 25% compared to a conventional case.

Accordingly, the crack risk in the bent area BA of the display device 1 may be reduced.

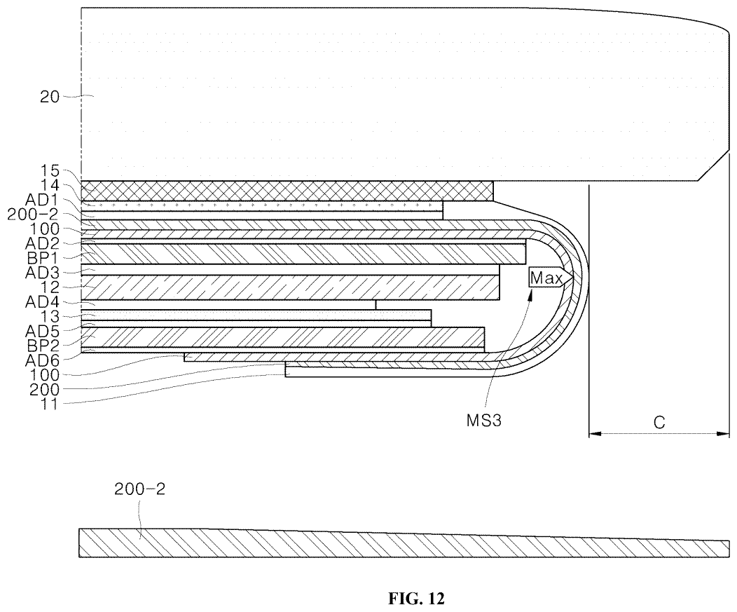

Referring to FIG. 12, when the sealing layer 200-2 according to still another exemplary embodiment of the present disclosure has a thickness that decreases as it extends from the first area 1A into the second area 2A through the bent area BA, the third area 3A may be changed to a third changed area C. A size of the third changed area C is smaller than the size of the third area 3A. When the sealing layer 200-2 is increasingly thinner as it extends from the display area AA into the bent area BA, the system space C of the display device 1 may be futher reduced, and accordingly, the bezel area BAZ may be further reduced.

In this case, a third maximum strain (MS3) value of the source-drain metal layer in the bent area BA may be improved by about 21% compared to a conventional case.

Accordingly, the crack risk in the bent area BA of the display device 1 may be reduced.

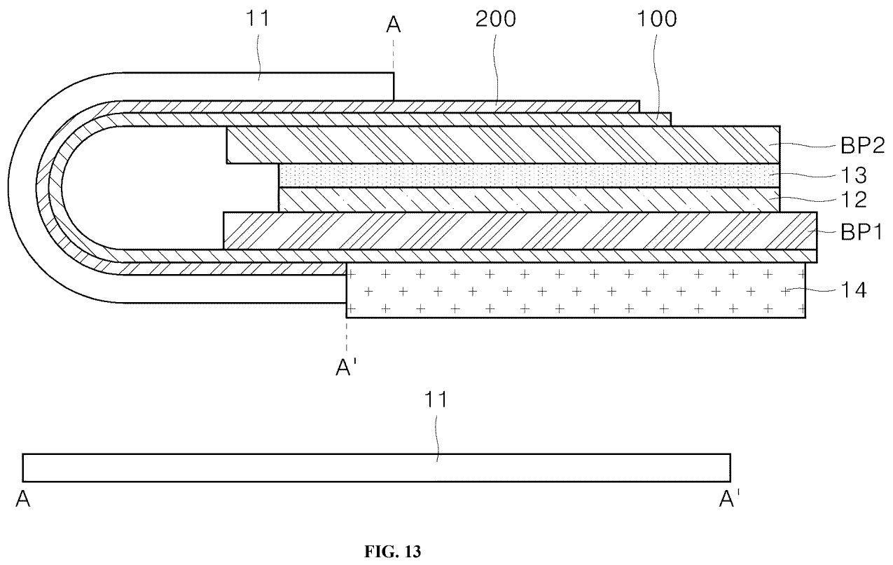

FIGS. 13 to 15 are diagrams showing examples of a change in the thickness of the sealing layer based on a change in a thickness of the reinforcement member according to an exemplary embodiment of the present disclosure.

Referring to FIG. 13, the bent portion of the reinforcement member 11 according to an exemplary embodiment of the present disclosure is disposed on the outer surface of the bent portion of the sealing layer 200 and has a constant thickness along a first section A-A′. In this regard, the sealing layer 200 may have a constant thickness.

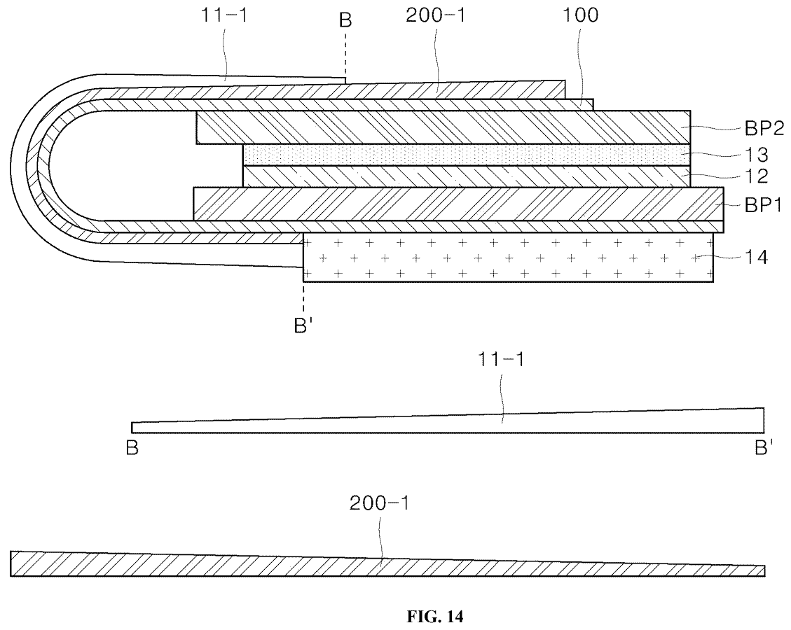

Referring to FIG. 14, a bent portion of a reinforcement member 11-1 according to another exemplary embodiment of the present disclosure may be disposed on the outer surface of the bent portion of the sealing layer 200-1 and has a thickness that gradually increases as it extends from a B point to a B′ point in a second section B-B′. In this regard, the sealing layer 200-1 may have a thickness that gradually becomes smaller as it extends from the B point to the B′ point in the second section B-B′.

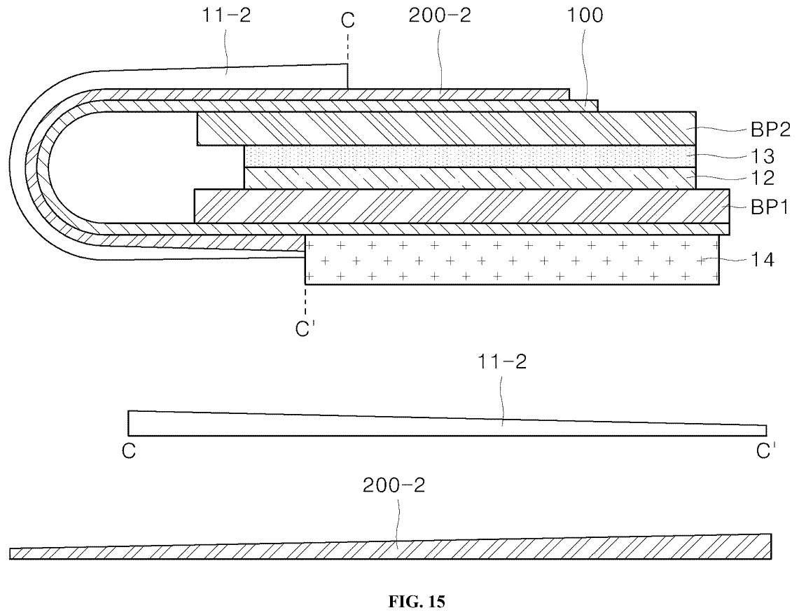

Referring to FIG. 15, a bent portion of a reinforcement member 11-2 according to still another exemplary embodiment of the present disclosure may be disposed on the outer surface of the bent portion of the sealing layer 200-2 and has a thickness that gradually decreases as it extends from a C point to a C′ point in a second section C-C′. In this regard, the sealing layer 200-2 may have a thickness that gradually becomes larger as it extends from the C point to the C′ point in the second section C-C′.

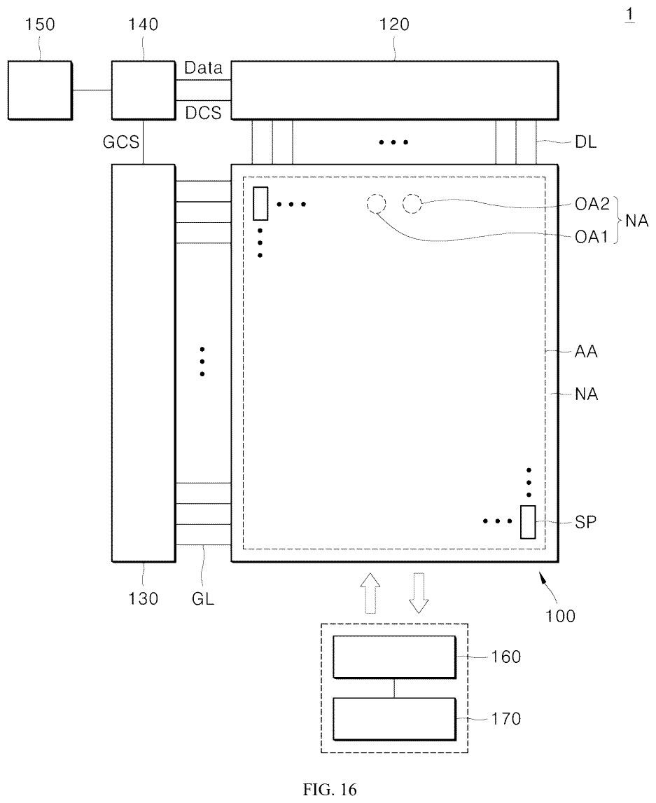

FIG. 16 is a block diagram schematically showing a system configuration of the display device according to an exemplary embodiment of the present disclosure.

Referring to FIG. 16, the display device 1 according to an exemplary embodiment of the present disclosure may include the display panel 100 and a display driver circuit.

The display driver circuit refers to a circuit for driving the display panel 100 and may include a data driver 120, a gate driver 130, and a controller 140.

The display panel 100 may include a display area AA where an image is displayed and a non-display area NA where an image is not displayed. The non-display area NA may be out of the display area AA, and is also referred to as the bezel area BZA. An entirety or a portion of the non-display area NA may be visible to a viewer in front of the display device 1, or may be bent and thus may be invisible to the viewer in front of the display device.

The display panel 100 may include a substrate SUB and a plurality of sub-pixels SP disposed on the substrate SUB. Furthermore, the display panel 100 may further include various types of signal lines to drive a plurality of sub-pixels SP.

The display device 1 according to some exemplary embodiments of the present disclosure may be a liquid crystal display device. Alternatively, the display device 1 according to some exemplary embodiments of the present disclosure may include the display panel 100 which emits light on its own. When the display device 1 according to some exemplary embodiments of the present disclosure is a self-luminous display device, each of the plurality of sub-pixels SP may include a light-emitting element.

For example, the display device 1 according to some exemplary embodiments of the present disclosure may be an organic light emitting display device in which the light-emitting element is embodied as an organic light emitting diode (OLED). In another example, the display device 1 according to some exemplary embodiments of the present disclosure may be an inorganic light-emitting display device in which the light-emitting element is embodied as an inorganic-based light-emitting diode. In still another example, the display device 1 according to some exemplary embodiments of the present disclosure may be a quantum dot display device in which a light-emitting element is embodied as a quantum dot as a semiconductor crystal that emits light on its own.

Depending on the type of the display device 1, a structure of each of the plurality of sub-pixels SP may vary. For example, when the display device 1 is a self-emitting display device in which the sub-pixel SP emits light on its own, each sub-pixel SP may include a light-emitting element that emits light on its own, one or more transistors, and one or more capacitors.

For example, various types of signal lines may include a plurality of data lines DL that carry data signals (also referred to as data voltages or image signals) and a plurality of gate lines GL carrying gate signals (also referred to as scan signals).

The plurality of data lines DL and the plurality of gate lines GL may intersect each other. Each of the plurality of data lines DL may extend in a first direction. Each of the plurality of gate lines GL may extend in a second direction.

In this regard, the first direction may be a column direction, and the second direction may be a row direction. Alternatively, the first direction may be a row direction, and the second direction may be a column direction.

The data driver 120 may be configured to drive the plurality of data lines DL and may output the data signals to the plurality of data lines DL. The data driver 120 may supply data voltage to the display panel 100.

The gate driver 130 may be configured to drive the plurality of gate lines GL and may output the gate signals to the plurality of gate lines GL. The gate driver 130 may supply the gate signal to the display panel 100.

The controller 140 may be configured to control the data driver 120 and the gate driver 130. The controller 140 may control a driving timing of the plurality of data lines DL and a driving timing of the plurality of gate lines GL.

The controller 140 may supply a data drive control signal DCS to the data driver 120 in order to control the data driver 120. The controller 140 may supply a gate drive control signal GCS to the gate driver 130 in order to control the gate driver 130.

The controller 140 may receive input image data from a host system 150 and supply image data Data to the data driver 120 based on the input image data.

The data driver 120 may supply the data signals to the plurality of data lines DL under the driving timing control of the controller 140.

The data driver 120 may receive the image data Data in a digital form from the controller 140, may convert the received image data Data into a data signal in an analog form, and may output the data signal to the plurality of data lines DL.

The gate driver 130 may supply the gate signals to the plurality of gate lines GL under the timing control of the controller 140. The gate driver 130 may receive a first gate voltage corresponding to a turn-on level voltage and a second gate voltage corresponding to a turn-off level voltage along with various gate driving control signals GCS and generate the gate signals based on the received voltages and signals, and may supply the generated gate signals to the plurality of gate lines GL.

For example, the data driver 120 may be connected to the display panel 100 using a TAB (Tape Automated Bonding) scheme, or may be connected to a bonding pad of the display panel 100 in a chip-on glass (COG) scheme or a chip-on panel (COP) scheme or may be connected to the display panel 100 in a chip-on film (COF) scheme.

The gate driver 130 may be connected to the display panel 100 using a tape automated bonding (TAB) scheme, or may be connected to the bonding pad of the display panel 100 using a chip-on-glass (COG) or chip-on panel (COP) scheme, or may be connected to the display panel 100 in the chip-on film (COF) scheme. Alternatively, the gate driver 130 may be of a gate in panel (GIP) type and may be formed in the non-display area NA of the display panel 100. The gate driver 130 may be disposed on the substrate SUB or connected to the substrate SUB. That is, when the gate driver 130 is of the gate in panel (GIP) type, the gate driver may be disposed in the non-display area NA of the substrate SUB. The gate driver 130 may be connected to the substrate when the gate driver is of a chip-on-glass (COG) type or a chip-on film (COF) type.

In one example, at least one of the data driver 120 and the gate driver 130 may be disposed in the display area AA of the display panel 100. For example, at least one of the data driver 120 and the gate driver 130 may be disposed not to overlap the sub-pixels SP, or may be disposed to partially or entirely overlap with the sub-pixels SP.

The data driver 120 may be connected to one side (e.g., upper or lower side) of the display panel 100. Depending on a driving scheme, a panel design scheme, etc., the data driver 120 may be connected to both opposing sides (e.g., upper and lower sides) of the display panel 100, or may be connected to two or more of four sides of the display panel 100.

The gate driver 130 may be connected to one side (e.g., left or right side) of the display panel 100. Depending on the driving scheme, the display panel design scheme, etc., the gate driver 130 may be connected to both opposing sides (e.g., left and right sides) of the display panel 100, or may be connected to two or more of the four sides of the display panel 100.

The controller 140 may be embodied as a separate component from the data driver 120. Alternatively, the controller 140 and the data driver 120 may be integrated with each other into an integrated circuit.

The controller 140 may be embodied as a timing controller used in a typical display technology, or as a control device that includes the timing controller and may perform other control functions, or as a control device other than the timing controller, or as a circuit within the control device. The controller 140 may be implemented using various circuits or electronic components such as an Integrated Circuit (IC), Field Programmable Gate Array (FPGA), Application Specific Integrated Circuit (ASIC), or a processor.

The controller 140 may be electrically connected to the data driver 120 and the gate driver 130 through a printed circuit board (PCB), a flexible printed circuit board (FPCB), etc.

The controller 140 may transmit and receive signals to and from the data driver 120 through one or more predetermined interfaces. In this regard, for example, the interface may include a Low Voltage Differential Signaling (LVDS) interface, an EPI interface, and a Serial Peripheral Interface (SPI).

Referring to FIG. 16, the display device 1 according to some exemplary embodiments of the present disclosure may include one or more open areas OA from which at least a portion of the substrate SUB has been removed, without being limited thereto.

One or more electronic optical devices (not shown) may be disposed in an area at least partially overlapping with the open area OA. The one or more electronic optical devices may include, for example, one or more of a photographing device such as a camera (image sensor), and a detection sensor such as a proximity sensor, and an illuminance sensor, without being limited thereto.

For example, the photographing device such as a camera may be located under a first open area OA1, and the detection sensor may be located under a second open area OA2.

The electronic optical device may be located under the substrate SUB, and the electronic optical device may be located so as to at least partially overlap the open area OA.

Each of the first open area OA1 and the second open area OA2 may have various shapes such as circular, oval, square, hexagon, or octagon. The shapes of the first open area OA1 and the second open area OA2 may be the same as or different from each other. An area size of the first open area OA1 may be the same as, or may be different from an area size of the second open area OA2.

For convenience of description, an example in which the shape of each of the first open area OA1 and the second open area OA2 is circular, and the area sizes thereof are equal to each other is described. However, the present disclosure is not limited thereto.

In one example, the one or more open areas OA may be located in an area where the substrate SUB has been removed. The open area OA may be a non-display area NA in which the sub-pixel SP is not disposed, without being limited thereto. As an example, the open area OA may be a display area AA in which the sub-pixel SP is disposed.

The open area OA located in the display area AA is referred to as a HiAA (Hole in Active Area).

The signal lines (e.g., data lines DL, gate lines GL, etc.) disposed on the substrate SUB may bypass the open area OA.

The display device 1 according to some exemplary embodiments of the present disclosure may include a touch sensor and a touch sensing circuit that detects whether a touch by a touch object such as a finger or a pen has occurred or a touch position, based on a sensing result of the touch sensor, in order to provide not only an image display function but also a touch sensing function.

The touch sensing circuit includes a touch driver circuit 160 that drives and senses the touch sensor to generate and output touch sensing data, and a touch controller 170 that detects whether the touch has occurred, or the location of the touch, based on the touch sensing data.

The touch sensor may include a plurality of touch electrodes. The touch sensor may further include a plurality of touch lines to electrically connect the plurality of touch electrodes to the touch driver circuit 160.

The touch sensor may be present outside the display panel 100 in a form of a touch panel, or may be present inside the display panel 100.

When the touch sensor is present outside the display panel 100 in the form of the touch panel, the touch sensor may be of an external type. When the touch sensor is of the external type, the touch panel and the display panel 100 may be manufactured separately and combined with each other during an assembly process. The touch panel of the external type may include a substrate for a touch panel and the plurality of touch electrodes on the substrate for the touch panel.

When the touch sensor is present inside the display panel 100, the touch sensor along with the signal lines and the electrodes related to display operation may be formed in the substrate SUB during the manufacturing process of the display panel 100.

The touch driver circuit 160 may supply a touch driving signal to at least one of the plurality of touch electrodes and sense the at least one of the plurality of touch electrodes and generate the touch sensing data based on the sensing result.

The touch sensing circuit may perform touch sensing in a self-capacitance sensing scheme or a mutual-capacitance sensing scheme.

When the touch sensing circuit performs the touch sensing in the self-capacitance sensing scheme, the touch sensing circuit may perform touch sensing based on a capacitance between each touch electrode and the touch object (e.g., finger, pen, etc.).

According to the self-capacitance sensing scheme, each of the plurality of touch electrodes may play a role of a driving touch electrode and a sensing touch electrode. The touch driver circuit 160 may drive all or some of the plurality of touch electrodes and sense all or some of the plurality of touch electrodes.

When the touch sensing circuit performs the touch sensing in the mutual-capacitance sensing scheme, the touch sensing circuit may perform touch sensing based on a capacitance between the touch electrodes.

According to the mutual-capacitance sensing scheme, the plurality of touch electrodes may be classified into driving touch electrodes and sensing touch electrodes. The touch driver circuit 160 may drive the driving touch electrodes and sense the sensing touch electrodes.

The touch driver circuit 160 and the touch controller 170 included in the touch sensing circuit may be embodied as separate devices or as a single device. Furthermore, the touch driver circuit 160 and the data driver circuit 120 may be embodied as separate devices or as a single device.

The display device 1 may further include a power supply circuit that supplies various types of power to the display driver circuit and/or the touch sensing circuit.

The display device 1 according to some exemplary embodiments of the present disclosure may embodied as a mobile terminal such as a smart phone or a tablet, or monitors or televisions (TV) of various sizes, However, the present disclosure is not limited thereto. The display device 1 according to some exemplary embodiments of the present disclosure may be embodied as a display device capable of displaying information or images and having various types and sizes.

As described above, according to the present disclosure, the bezel area of the display device may be reduced, the rigidity of the display panel may be improved, such that the crack defects in the bent portion may be reduced, thereby realizing the display device that prevents the quality defects, ensures the reliability, and implements a narrow bezel.

Further, according to the present disclosure, the display device may be realized in which the thickness of the reinforcement member to reinforce the bent portion of the display panel may be adjusted, and the sealing layer on the display panel in the display area may extend into the bent area in the non-display area, and the thickness of the reinforcement member may be adjusted based on the shape of the extending portion of the sealing layer.

Although the embodiments of the present disclosure have been described in more detail with reference to the accompanying drawings, the present disclosure is not necessarily limited to these embodiments, and may be modified in a various manner within the scope of the technical spirit of the present disclosure. Accordingly, the embodiments as disclosed in the present disclosure are intended to describe rather than limit the technical idea of the present disclosure, and the scope of the technical idea of the present disclosure is not limited by these embodiments. Therefore, it should be understood that the embodiments described above are not restrictive but illustrative in all respects.

What is claimed is:

1. A display device comprising:
a display panel including:
a first area constituting a front surface of the display panel and including a display area and a bezel area;
a bent area disposed under the first area; and
a second area constituting a rear surface of the display panel and disposed under the bent area; and
a sealing layer disposed on top of the display panel in the first area, disposed on an outer surface of a bent portion of the display panel in the bent area, and disposed under the display panel in the second area.

2. The display device of claim 1, further comprising:
a reinforcement member disposed on an outer surface of a bent portion of the sealing layer in the bent area, and disposed under the sealing layer in the second area.

3. The display device of claim 2, wherein the reinforcement member is further disposed on a portion of a top surface of the sealing layer in the first area.

4. The display device of claim 2, further comprising:
a cover member disposed on top of the sealing layer in the first area;
a back frame disposed under the cover member in the bezel area and disposed under the reinforcement member and the bent portion of the display panel in the second area to support the cover member and the display panel.

5. The display device of claim 2, wherein the reinforcement member includes a micro coating layer.

6. The display device of claim 2, wherein the reinforcement member includes an ultraviolet curable acrylic resin, and
wherein the sealing layer includes aluminum nanoparticles.

7. The display device of claim 2, wherein the display panel is bent at a constant curvature in the bent area.

8. The display device of claim 1, wherein the sealing layer has a flat shape in the first area, a bent shape bent downwardly in the bent area, and a flat shape in the second area.

9. The display device of claim 4, wherein the back frame contacts with the cover member in the bezel area, and contacts with the reinforcement member and the bent portion of the display panel in the second area.

10. The display device of claim 4, wherein the back frame contacts with a side surface of the reinforcement member in the bent area.

11. The display device of claim 1, wherein the sealing layer includes an epoxy resin.

12. The display device of claim 1, wherein the display panel has a flat shape in the first area, a bent shape bent downwardly in the bent area, and a flat shape in the second area.

13. The display device of claim 1, further comprising:
a first support member disposed under the display panel and supporting the display panel in the first area;
a second support member disposed on top of the bent portion of the display panel and supporting the bent portion of the display panel in the second area; and
a plate disposed between the first support member and the second support member.

14. The display device of claim 13, further comprising a connection member disposed between the second support member and the plate to fix the bent portion of the display panel.

15. The display device of claim 14, wherein the connection member includes at least one layer and is made of at least one material selected from a group consisting of optical clear adhesive OCA, optical clear resin OCR, and pressure-sensitive adhesive PSA.

16. The display device of claim 14, wherein the connection member is embodied as a foam tape or a foam pad and includes a conductive tape or a conductive double-sided tape.

17. The display device of claim 13, wherein the plate is made of a metal material.

18. The display device of claim 1, wherein the sealing layer has a constant thickness across the first area, the bent area, and the second area.

19. The display device of claim 1, wherein the sealing layer has different thickness in the first area and the second area.

20. The display device of claim 1, wherein the sealing layer has a greater thickness in the second area than a thickness in the first area.

21. The display device of claim 1, wherein the sealing layer has a greater thickness in the first area than a thickness in the second area.

22. The display device of claim 1, wherein the sealing layer includes an organic material.

23. The display device of claim 1, wherein the display panel includes an encapsulation layer,
wherein the encapsulation layer includes a first encapsulation layer embodied as an inorganic film, a second encapsulation layer embodied as an organic film and disposed on the first encapsulation layer, and a third encapsulation layer embodied as an inorganic film and disposed on the second encapsulation layer.

24. The display device of claim 23, further comprising:
a touch buffer film disposed on the third encapsulation layer;
a touch sensor and a touch interlayer insulating film disposed on the touch buffer film; and
a touch protective film disposed on the touch sensor and the touch interlayer insulating film,
wherein the sealing layer is disposed on the touch protective film.

25. The display device of claim 24, wherein the touch sensor includes touch sensor metals and a bridge metal located at different layers.

26. The display device of claim 2, further comprising a polarizing layer disposed on the sealing layer in the first area,
wherein the reinforcement member contacts with a side surface of the polarization layer in the first area, and extends to the bent area from the side surface of the polarization layer.

27. The display device of claim 2, wherein the reinforcement member covers an end of the sealing layer in the second area.

28. The display device of claim 1, wherein the sealing layer covers a portion of the display panel in the second area, and exposes an end of the display panel in the second area.

29. The display device of claim 1, further comprising
a gate driver configured to supply a gate signal to the display panel;
a data driver configured to supply a data voltage to the display panel; and
a controller configured to control the gate driver and the data driver.

30. The display device of claim 1, further comprising:
a polarizing layer disposed on the sealing layer through a first adhesive layer;
a cover member disposed on the polarizing layer through an optical adhesive layer;
a first support member disposed under the display panel through a second adhesive layer;
a plate disposed under the first support member through a third adhesive layer;
a connection member disposed under the plate through a fourth adhesive layer; and
a second support member disposed under the connection member through a fifth adhesive layer,
wherein the bent portion of the display panel is disposed under the second support member through a sixth adhesive layer,
wherein a bent portion of the sealing layer is disposed under the bent portion of the display panel,
wherein a reinforcement member is disposed under the bent portion of the sealing layer.

31. The display device of claim 1, wherein in the bent area, an area inwardly of the bent portion of the display panel is filled with a resin including an organic insulating material.

32. The display device of claim 13, wherein the plate is made of one or a combination of stainless steel, glass, ceramic, and metal.

33. The display device of claim 13, wherein the plate is made of a plastic material including at least one of polycarbonate, polyimide, polyethylene naphthalate, and polyethylene terephthalate.
